(19) United States
(12) Patent Application Publication
(10) Pub. No.: US 2026/0271258 A1
(43) Pub. Date: Sep. 10, 2026

(54) SEMICONDUCTOR DEVICE

(71) Applicant: Taiwan Semiconductor Manufacturing Company, Ltd., Hsinchu (TW)

(72) Inventor: Jhon-Jhy LIAW, Zhudong Township (TW)

(73) Assignee: Taiwan Semiconductor Manufacturing Company, Ltd., Hsinchu (TW)

(21) Appl. No.: 19/074,041

(22) Filed: Mar. 7, 2025

(51) Int. Cl. H10B 10/00; H01L 23/522; H01L 23/528; H10D 30/00; H10D 30/43; H10D 62/10

(52) U.S. Cl. CPC H10B 10/12; H10D 30/43; H10D 30/502; H10D 62/121; H10W 20/42; H10W 20/427; H10W 20/435; H10W 20/495

(57) ABSTRACT

A semiconductor device includes a first transistor cell having a first cell boundary lengthwise extending in a first direction. The first transistor includes a first active area and a second active area extending in the first direction and arranged in a second direction perpendicular to the first direction, an isolation feature between the first active area and the second active area, and gate structures across the first active area and the second active area and interfacing a top surface of the isolation feature. The semiconductor device further includes a first backside power conductor under and lengthwise overlapping the first active area, and a second backside power conductor under and lengthwise overlapping the second active area. The first backside power conductor and the second backside power conductor are electrically connected to the first transistor cell.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, fin field-effect transistors (FinFETs) and gate-all-around (GAA) transistors have been incorporated into semiconductor devices (including, for example, static random-access memory, or SRAM, cells) to reduce chip footprint while maintaining reasonable processing margins.

However, as semiconductor devices continue to be scaled down, interconnection routing for semiconductor devices uses too many routing resources and therefore impacts the cell scaling as well as memory performance. Accordingly, although existing technologies for fabricating semiconductor devices have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a fragmentary diagrammatic top view of an integrated circuit (IC) chip, in portion or entirety, in accordance with some embodiments of the present disclosure.

FIGS. 2 and 3 illustrates circuit diagrams of an SRAM circuit that can be implemented in an SRAM cell of an array in the memory region of the IC chip in FIG. 1, in accordance with some embodiments of the present disclosure.

FIG. 4 illustrates a perspective view of a GAA transistor in an SRAM cell in accordance with some embodiments of the present disclosure.

FIG. 5 shows a cross-sectional view of a semiconductor device for illustrating a frontside interconnection structure and a backside interconnection structure, in accordance with some embodiments of the present disclosure.

FIG. 6 illustrates a schematic illustration of an array of SRAM cells that can be implemented in a memory region of the IC chip in FIG. 1, in accordance with some embodiments of the present disclosure.

FIGS. 7A and 7B illustrate top views (or layouts) of features in a device region and a frontside interconnection structure of two adjacent SRAM cells in a portion of an array in a semiconductor device that can be one embodiment of the SRAM cells implemented in the memory region, in accordance with some embodiments of the present disclosure.

FIG. 7C illustrates a top view (or a layout) of the features in the device region and a backside interconnection structure of the two adjacent SRAM cells in the portion of the array in the semiconductor device that can be one embodiment of the SRAM cells implemented in the memory region, in accordance with some embodiments of the present disclosure.

FIG. 7D is an X-Z cross-sectional view of the array in the semiconductor device along a line D-D′ in FIGS. 7A to 7C, in accordance with some embodiments of the present disclosure.

FIG. 7E is an X-Z cross-sectional view of the array in the semiconductor device along a line E-E′ in FIGS. 7A to 7C, in accordance with some embodiments of the present disclosure.

FIG. 7F is a Y-Z cross-sectional view of the array in the semiconductor device along a line F-F′ in FIGS. 7A to 7C, in accordance with some embodiments of the present disclosure.

FIG. 7G is a Y-Z cross-sectional view of the array in the semiconductor device along a line G-G′ in FIGS. 7A to 7C, in accordance with some embodiments of the present disclosure.

FIG. 7H is a Y-Z cross-sectional view of the array in the semiconductor device along a line H-H′ in FIGS. 7A to 7C, in accordance with some embodiments of the present disclosure.

FIG. 7I is a Y-Z cross-sectional view of the array in the semiconductor device along a line I-I′ in FIGS. 7A to 7C, in accordance with some embodiments of the present disclosure.

FIG. 8A is a Y-Z cross-sectional view of the array in the semiconductor device along a line G-G′ in FIGS. 7A to 7C, in accordance with some alternative embodiments of the present disclosure.

FIG. 8B is a Y-Z cross-sectional view of the array in the semiconductor device along a line H-H′ in FIGS. 7A to 7C, in accordance with some alternative embodiments of the present disclosure.

FIG. 8C is a Y-Z cross-sectional view of the array in the semiconductor device along a line I-I′ in FIGS. 7A to 7C, in accordance with some alternative embodiments of the present disclosure.

FIGS. 9A, 9B, 9C, and 9D illustrate top views (or layouts) of features in a device region and a frontside interconnection structure of two adjacent SRAM cells in a portion of an array in a semiconductor device that can be one embodiment of the SRAM cells implemented in the memory region, in accordance with some alternative embodiments of the present disclosure.

FIG. 9E illustrates a top view (or a layout) of the features in the device region and a backside interconnection structure of the two adjacent SRAM cells in the portion of the array in the semiconductor device that can be one embodiment of the SRAM cells implemented in the memory region, in accordance with some alternative embodiments of the present disclosure.

FIG. 9F is an X-Z cross-sectional view of the array in the semiconductor device along a line F-F′ in FIGS. 9A to 9E, in accordance with some alternative embodiments of the present disclosure.

FIG. 9G is an X-Z cross-sectional view of the array in the semiconductor device along a line G-G′ in FIGS. 9A to 9E, in accordance with some alternative embodiments of the present disclosure.

FIG. 9H is a Y-Z cross-sectional view of the array in the semiconductor device along a line H-H′ in FIGS. 9A to 9E, in accordance with some alternative embodiments of the present disclosure.

FIG. 9I is a Y-Z cross-sectional view of the array in the semiconductor device along a line I-I′ in FIGS. 9A to 9E, in accordance with some alternative embodiments of the present disclosure.

FIG. 9J is a Y-Z cross-sectional view of the array in the semiconductor device along a line J-J′ in FIGS. 9A to 9E, in accordance with some alternative embodiments of the present disclosure.

FIG. 9K is a Y-Z cross-sectional view of the array in the semiconductor device along a line K-K′ in FIGS. 9A to 9E, in accordance with some alternative embodiments of the present disclosure.

FIGS. 10A and 10B illustrate top views (or layouts) of features in a device region and a frontside interconnection structure of two adjacent SRAM cells in a portion of an array in a semiconductor device that can be one embodiment of the SRAM cells implemented in the memory region, in accordance with some alternative embodiments of the present disclosure.

FIG. 10C illustrates a top view (or a layout) of the features in the device region and a backside interconnection structure of the two adjacent SRAM cells in the portion of the array in the semiconductor device that can be one embodiment of the SRAM cells implemented in the memory region, in accordance with some alternative embodiments of the present disclosure.

FIG. 10D is an X-Z cross-sectional view of the array in the semiconductor device along a line D-D′ in FIGS. 10A to 10C, in accordance with some alternative embodiments of the present disclosure.

FIG. 10E is an X-Z cross-sectional view of the array in the semiconductor device along a line E-E′ in FIGS. 10A to 10C, in accordance with some alternative embodiments of the present disclosure.

FIG. 10F is a Y-Z cross-sectional view of the array in the semiconductor device along a line F-F′ in FIGS. 10A to 10C, in accordance with some alternative embodiments of the present disclosure.

FIG. 10G is a Y-Z cross-sectional view of the array in the semiconductor device along a line G-G′ in FIGS. 10A to 10C, in accordance with alternative some embodiments of the present disclosure.

FIG. 10H is a Y-Z cross-sectional view of the array in the semiconductor device along a line H-H′ in FIGS. 10A to 10C, in accordance with alternative some embodiments of the present disclosure.

FIG. 10I is a Y-Z cross-sectional view of the array in the semiconductor device along a line I-I′ in FIGS. 10A to 10C, in accordance with some alternative embodiments of the present disclosure.

FIGS. 11A and 11B illustrate top views (or layouts) of features in a device region and a frontside interconnection structure of two adjacent SRAM cells in a portion of an array in a semiconductor device that can be one embodiment of the SRAM cells implemented in the memory region, in accordance with some alternative embodiments of the present disclosure.

FIG. 11C illustrates a top view (or a layout) of the features in the device region and a backside interconnection structure of the two adjacent SRAM cells in the portion of the array in the semiconductor device that can be one embodiment of the SRAM cells implemented in the memory region, in accordance with some alternative embodiments of the present disclosure.

FIG. 11D is an X-Z cross-sectional view of the array in the semiconductor device along a line D-D′ in FIGS. 11A to 11C, in accordance with some alternative embodiments of the present disclosure.

FIG. 11E is an X-Z cross-sectional view of the array in the semiconductor device along a line E-E′ in FIGS. 11A to 11C, in accordance with some alternative embodiments of the present disclosure.

FIG. 11F is a Y-Z cross-sectional view of the array in the semiconductor device along a line F-F′ in FIGS. 11A to 11C, in accordance with some alternative embodiments of the present disclosure.

FIG. 11G is a Y-Z cross-sectional view of the array in the semiconductor device in the semiconductor device along a line G-G′ in FIGS. 11A to 11C, in accordance with alternative some embodiments of the present disclosure.

FIG. 11H is a Y-Z cross-sectional view of the array in the semiconductor device along a line H-H′ in FIGS. 11A to 11C, in accordance with alternative some embodiments of the present disclosure.

FIG. 11I is a Y-Z cross-sectional view of the array in the semiconductor device along a line I-I′ in FIGS. 11A to 11C, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to static random-access memory (SRAM) cells having field-effect transistors (FETs), such as three-dimensional gate-all-around (GAA) transistors, in an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure also relates to layouts and structures thereof of semiconductor devices. More particularly, the present disclosure relates to SRAM cell layout designs and structures. The present disclosure provides a compact SRAM cell design having a width of four gate pitches (the so-called four-gate-pitch SRAM cell) and with multiple metal layers with metal conductors (or tracks) used for connections and over transistors. Transistors such as gate-all-around (GAA) transistors forming the SRAM cell are fabricated over a substrate. Some of the metal conductors, such as bit-line conductors and bit-line-bar (also referred to as complementary bit-line) conductors, are fabricated in the lowest metal layer in the frontside interconnection structure. Some of the metal conductors, such as VDD conductors and VSS conductors, are fabricated in the lowest metal layer in the backside interconnection structure. Other metal conductors, such as word-line conductors, are fabricated in higher metal layers in the frontside interconnection structure.

Therefore, the space at the frontside interconnection structure is relieved to reduce the routing complexity due to some metal conductors are in the backside interconnection structure. Furthermore, the metal conductors can be made wider to have low resistance, thereby improving the performance of the semiconductor devices. The bit-line conductors, the bit-line-bar conductors, the VDD conductors, and the VSS conductors fabricated in the lowest metal layer (in the frontside interconnection structure or the backside interconnection structure) have lower capacitance, thereby improving the performance of the semiconductor devices. The SRAM layout according to the present disclosure is process friendly and lithography friendly, enabling better process margin.

Embodiments of the present disclosure offer advantages over the existing art, though it should be understood that other embodiments may offer different advantages, not all advantages are necessarily discussed herein, and no particular advantage is required for all embodiments. For example, embodiments discussed herein include an array of SRAM cells, in which two SRAM cells in adjacent two rows have a bit-line conductor and a bit-line-bar conductor in the lowest metal layer in the frontside interconnection structure, and VDD and VSS conductors in the lowest metal layer in the backside interconnection structure, that can improve cell performance and reduce the routing complexity of the SRAM cell. The details of the present disclosure are described below in conjunction with the accompanying drawings, which illustrate the layout and structure of circuit cells, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated. The X-direction, the Y-direction, and the Z-direction can be arbitrarily referred to as the first direction, the second direction, or the third direction in the order of appearance. For example, the Z-direction can be referred to as the first direction, and one of the X-direction and the Y-direction can be referred to as the second direction, and the other one of the X-direction and the Y-direction can be referred to as the third direction.

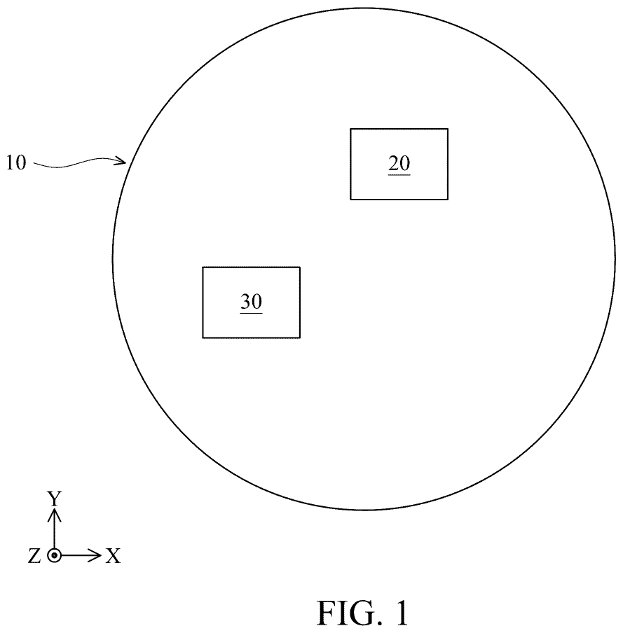

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, p-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or combinations thereof.

The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. In some embodiments, the IC chip 10 includes a memory region 20 and a logic region 30.

The memory region 20 can include an array of transistor cells for memory (i.e., memory cells), each of which includes transistors and interconnection structures (also referred to as routing structures) that combine to provide a storage device and/or a storage function, such as a flip flop, a latch, other suitable semiconductor devices, or a combination thereof. In some embodiments, the memory region 20 is configured with static random-access memory (SRAM) cells, dynamic random-access memory (DRAM) cells, non-volatile random-access memory (NVRAM) cells, flash memory cells, other suitable memory cells, or a combination thereof.

The logic region 30 can include an array of transistor cells for logic (i.e., logic cells) having various logic cells or standard (STD) cells. The logic cells or STD cells may include transistors and interconnection structures that combine to provide a logic device and/or a logic function, such as an inverter, an AND, a NAND, an OR, an NOR, a NOT, an XOR, an XNOR, other suitable logic devices, or combinations thereof. FIG. 1 has been simplified for the sake of clarity to better understand the inventive concepts of the present disclosure. Additional features can be added in IC chip 10, and some of the features described herein can be replaced, modified, or eliminated in other embodiments of the IC chip 10.

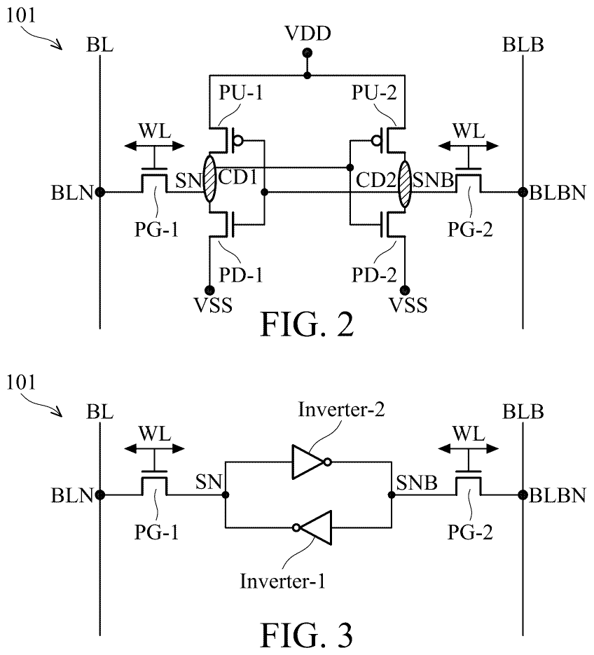

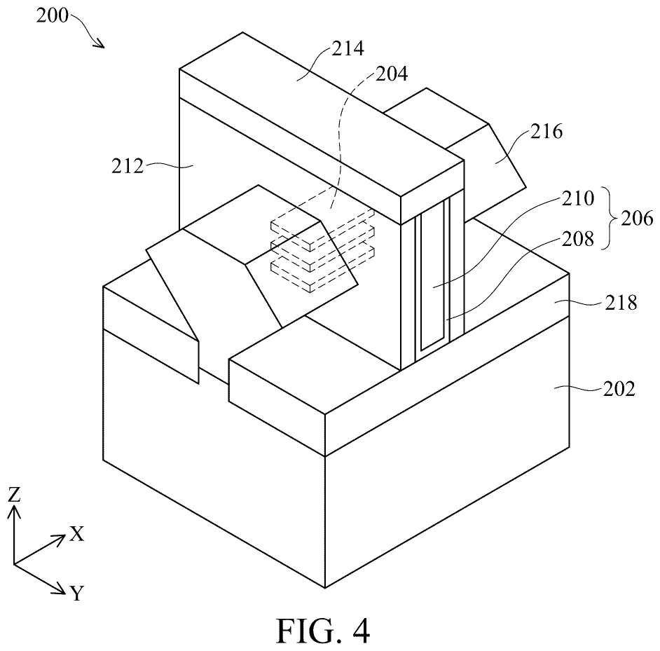

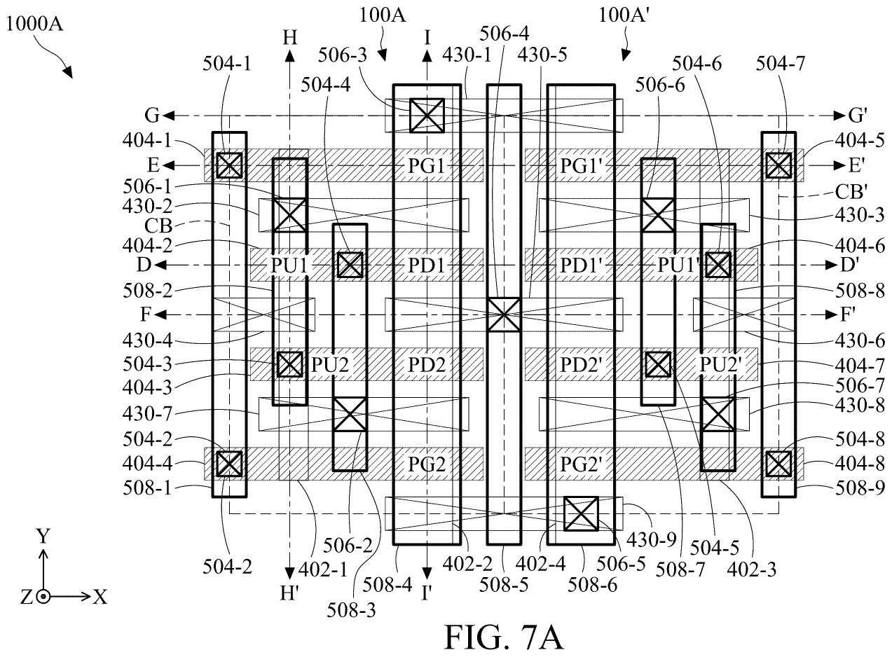

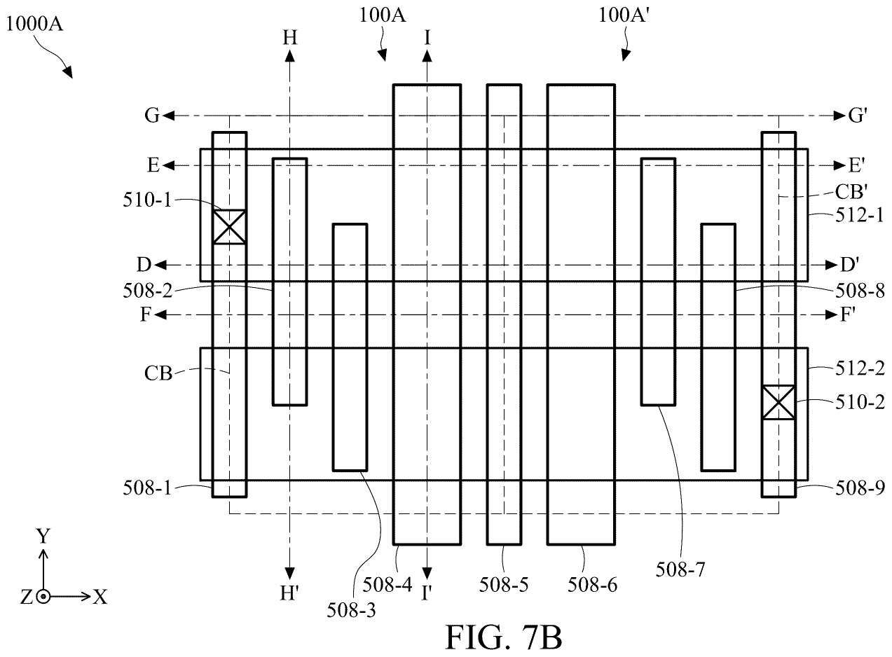

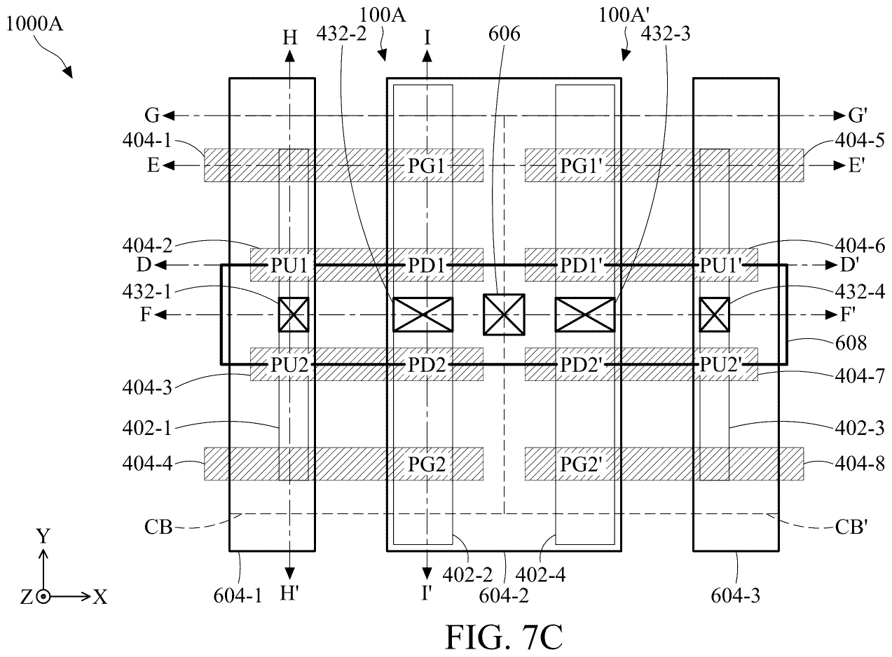

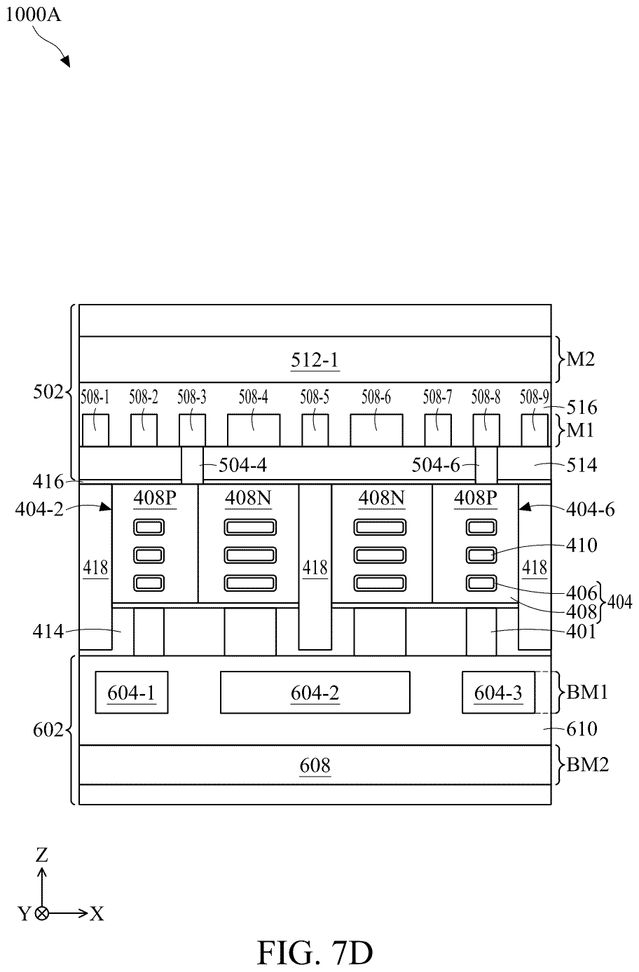

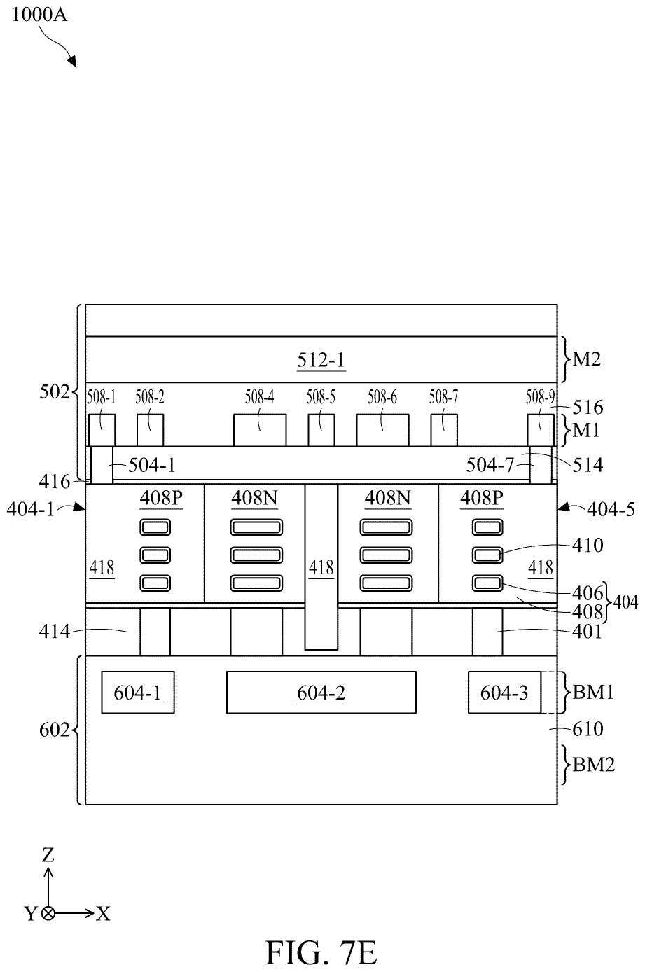

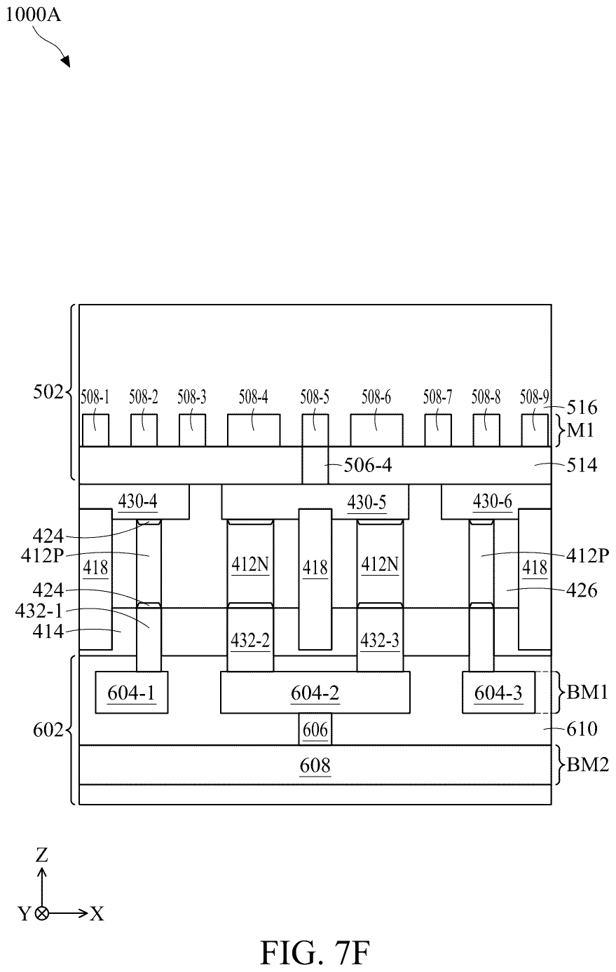

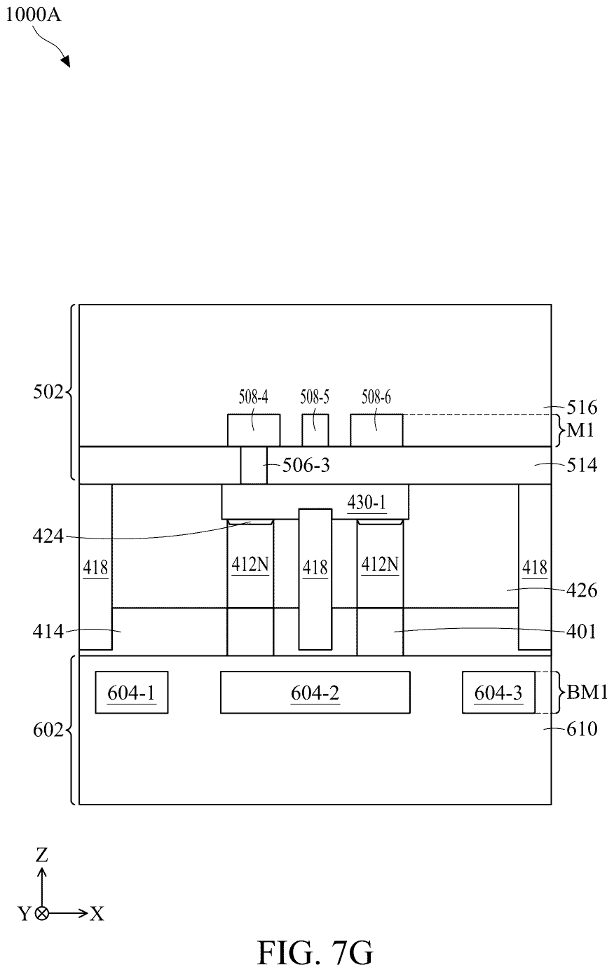

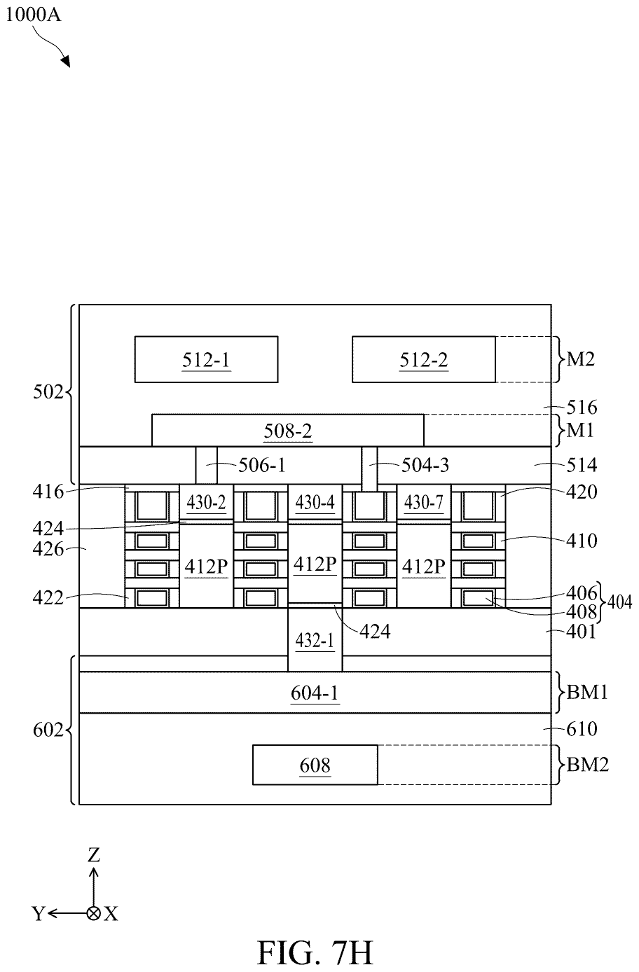

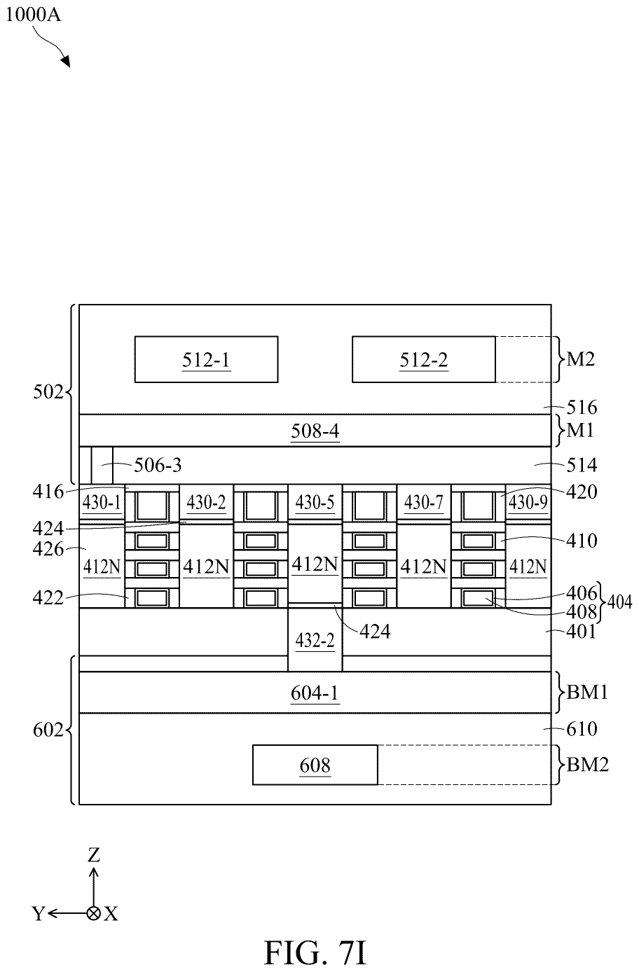

FIG. 2 and FIG. 3 are circuit diagrams of an SRAM circuit that can be implemented in an SRAM cell of an array in the memory region 20 of FIG. 1, in accordance with some alternative embodiments of the present disclosure. The circuit diagram of SRAM cell is merely exemplary, and in some embodiments, each of SRAM cells (e.g., SRAM cells 100A to 100D and 100A′ to 100D′ in FIGS. 7A to 18B) in the array is configured with an SRAM circuit similar to the SRAM cell 100 and as shown in FIG. 2 and FIG. 3. For example, each of SRAM cells has a storage portion that includes a cross-coupled pair of inverters (also referred to as a latch), such as an Inverter-1 and an Inverter-2. Inverter-1 includes pull-up transistor PU1 and pull-down transistor PD1, and Inverter-2 includes pull-up transistor PU2 and pull-down transistor PD2. Pass-gate transistor PG1 is connected to an output of Inverter-1 and an input of Inverter-2, and pass-gate transistor PG2 is connected to an output of Inverter-2 and an input of Inverter-1. In operation, pass-gate transistor PG1 and pass-gate transistor PG2 provide access to the storage portion of their respective SRAM cell (i.e., Inverter-1 and Inverter-2) and can also be referred to as access transistors of their respective SRAM cell. Each of SRAM cells (e.g., the SRAM cells 100A to 100D and 100A′ to 100D′ in FIGS. 7A to 18B) is connected to and powered through a first power supply voltage, such as a positive power supply voltage, and a second power supply voltage, such as a ground voltage or a reference voltage (which can be an electrical ground). A gate of pull-up transistor PU1 interposes a source, which is electrically coupled to the first power supply voltage via a voltage node (or voltage source) VDD, and a first common drain (CD1) (i.e., a drain of pull-up transistor PU1 and a drain of pull-down transistor PD1). A gate of pull-down transistor PD1 interposes a source, which is electrically coupled to the second power supply voltage via a voltage node (or voltage source) VSS, and the first common drain. A gate of pull-up transistor PU2 interposes a source, which is electrically coupled to the first power supply voltage via voltage node VDD, and a second common drain (CD-2) (i.e., a drain of pull-up transistor PU2 and a drain of pull-down transistor PD2). A gate of pull-down transistor PD2 interposes a source, which is electrically coupled to the second power supply voltage via voltage node VSS, and the second common drain. The first common drain provides a storage node SN that stores data in true form, and the second common drain provides a storage node SNB that stores data in complementary form, or vice versa, in some embodiments. The gate of pull-up transistor PU1 and the gate of pull-down transistor PD1 are coupled together and to the second common drain SD2, and the gate of pull-up transistor PU2 and the gate of pull-down transistor PD2 are coupled together and to the first common drain SD1. A gate of pass-gate transistor PG1 interposes a drain connected to a bit line node BLN, which is electrically coupled to a bit-line BL, and a source, which is electrically coupled to the first common drain CD1. A gate of pass-gate transistor PG2 interposes a drain connected to a complementary bit line node BLBN, which is electrically coupled to a bit-line-bar (complementary bit-line) BLB, and a source, which is electrically coupled to the second common drain CD2. Gates of pass-gate transistors PG1, PG2 are connected to and controlled by a word line WL, which allows selection of a respective SRAM cell, such as the SRAM cell 100A, for reading and/or writing. In some embodiments, pass-gate transistors PG1, PG2 provide access to storage nodes SN, SNB, respectively, each of which can store a bit (e.g., a logical 0 or a logical 1), during read operations and/or write operations. For example, pass-gate transistors PG1, PG2 couple storage nodes SN, SNB, respectively, to bit-line BL and bit-line-bar BLB in response to voltage applied to gates of pass-gate transistors PG1, PG2 by word line WL. In some embodiments, SRAM cells are single-port SRAMs. In some embodiments, SRAM cells are configured as multi-port SRAMs, such as dual-port SRAMs, and/or with more or less transistors than depicted, such as 8T SRAMs. FIG. 2 and FIG. 3 have been simplified for the sake of clarity to better understand the inventive concepts of the present disclosure. Additional features can be added in the SRAM circuits of FIG. 2 and FIG. 3, and some of the features described herein can be replaced, modified, or eliminated in other embodiments of the SRAM circuits of FIG. 2 and FIG. 3.

Each of the SRAM cells discussed above is constructed by transistors, such that the SRAM cells herein may also be referred to as transistor cells. The transistors may be planar transistors, fin field-effect transistor (FinFET) transistors, gate-all-around (GAA) transistors, nano-wire transistors, nano-sheet transistors, or a combination thereof. For the sake of providing an example, an exemplary GAA transistor is illustrated in FIG. 4. However, it should be understood that the application should not be limited to a particular type of device, except as specifically claimed.

Referring to FIG. 4, a perspective view of an exemplary GAA transistor 200 is illustrated. The GAA transistor 200 is formed over a substrate 202. The substrate 202 may contains a semiconductor material, such as bulk silicon (Si).

The GAA transistor 200 also includes one or more nanostructures 204 (dash lines) extending in an X-direction and vertically stacked (or arranged) in a Z-direction. More specifically, the nanostructures 204 are spaced from each other in the Z-direction. In some embodiments, the nanostructures 204 may also be referred to as channels, channel layers, nanosheets, or nanowires.

The GAA transistor 200 further includes a gate structure 206 including a gate dielectric layer 208 and a gate electrode layer 210. The gate dielectric layer 208 wraps around the nanostructures 204 and the gate electrode layer 210 wraps around the gate dielectric layer 208 (not shown in FIG. 4, may refer to FIGS. 7D, 7E, 7H, and 7I). As shown in FIG. 4, gate spacers 212 are on sidewalls of the gate structure 206 and over the nanostructures 204 (not shown in FIG. 2, may refer to FIGS. 7F and 7G). A gate top dielectric layer 214 is over the gate dielectric layer 208, the gate electrode layer 210, and the nanostructures 204. The gate top dielectric layer 214 is used for contact etch protection layer.

The GAA transistor 200 further includes source/drain features 216. As shown in FIG. 4, two source/drain features 216 are on opposite sides of the gate structure 206. The nanostructures 204 (dash lines) extends in the X-direction to connect one source/drain feature 216 to the other source/drain feature 216. The source/drain features 216 may also be referred to as source/drain, or source/drain regions. In some embodiments, source/drain feature(s) may refer to a source or a drain, individually or collectively dependent upon the context.

Isolation feature 218 is over the substrate 202 and under the gate dielectric layer 208, the gate electrode layer 210, and the gate spacers 212. The isolation feature 218 is used for isolating the GAA transistor 200 from other devices. In some embodiments, the isolation feature 218 may include different structures, such as shallow trench isolation (STI) structure, deep trench isolation (DTI) structure. Therefore, the isolation feature 218 is also referred as to as a STI feature or DTI feature.

Generally, interconnection of devices and transistor cells are disposed over or at frontside of transistors to form desired circuit routing. As transistors and transistor cells continue to be scaled down, space for interconnection routing is also decreased. In order to achieve desired circuit routing, metal conductor width and conductor-to-conductor space are decreased, thereby increasing resistance and parasitic capacitance to impact performance of devices and transistor cells. In some embodiments of present disclosure, a part of interconnection of devices and transistor cells is disposed under or at backside of transistors to improve upon the above issue.

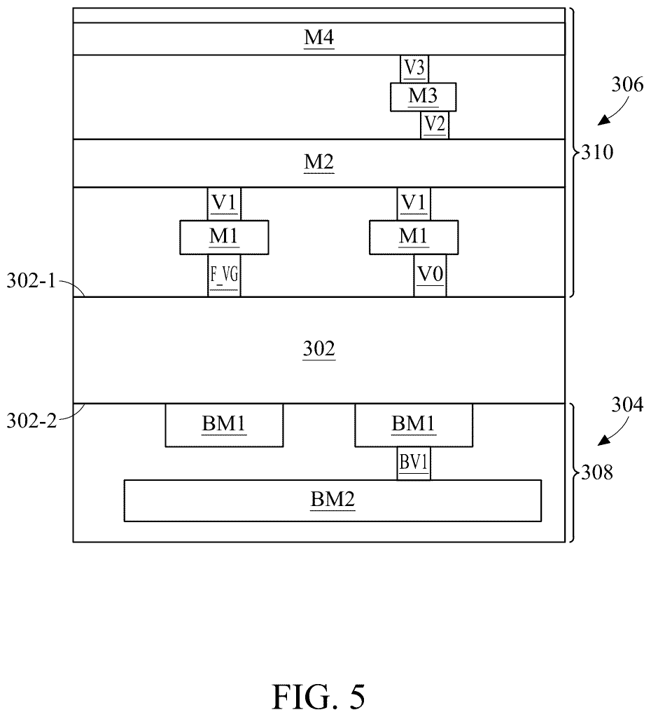

FIG. 5 shows a cross-sectional view of a semiconductor device 300 for illustrating a frontside interconnection structure and a backside interconnection structure, in accordance with some embodiments of the present disclosure. The semiconductor device 300 has device region 302 (also referred to as a device layer), a backside interconnection structure 304, and a frontside interconnection structure 306. The device region 302 is the region where the transistors and main features are located, such as gate, channel, source/drain, contact features, and the transistors (e.g., the transistors of the SRAM cell 100 discussed above) of the transistor cells discussed above. The device region 302 has a front side 302-1 and a back side 302-2. The backside interconnection structure 304 is under the device region 302 or at the back side 302-2 of the device region 302, and the frontside interconnection structure 306 is over the device region 302 or at the front side 302-1 of the device region 302.

As shown in FIG. 5, the backside interconnection structure 304 includes an inter-metal dielectric (IMD) 308, a metal layer BM1, and a metal layer BM2 under the metal layer M1. Each of the metal layers BM1 and BM2 includes metal conductors. The backside interconnection structure 304 further includes vias BV1 for connecting the metal conductor in the underlying metal layer to the metal conductor in the overlying metal layer. The frontside interconnection structure 306 includes an inter-metal dielectric (IMD) layer 310, a metal layer M1, a metal layer M2 over the metal layer M1, a metal layer M3 over the metal layer M2, and a metal layer M4 over the metal layer M3. Each of the metal layers M1, M2, M3, and M4 includes metal conductors. The frontside interconnection structure 306 further includes vias F_VG, V0, V1, V2, and V3 for connecting the metal conductor in the underlying metal layer to the metal conductor in the overlying metal layer.

The vias and metal conductors in the IMD layers 308 and 310 electrically couple various transistors and/or components (for example, gate, source/drain features, resistors, capacitors, and/or inductors) in the device region 302, such that the various devices and/or components can operate as specified by the design requirements of circuit cells (e.g., logic cells and memory cells). It should be noted that there may be more vias and metal conductors in the IMD layers 308 and 310 for connections. The IMD layers 308 and 310 may be multilayer structure, such as one or more dielectric layers.

Since the backside interconnection structure 304 is at the backside 302-2 of the device region 302, the IMD layer 308, the vias BV1, and the metal conductors in the metal layers BM1 and BM2 may also be referred to as the backside IMD layer, the backside vias, and the backside metal conductors, respectively. Since the frontside interconnection structure 306 is at the frontside 302-1 of the device region 302, the IMD layer 310, the vias F_VG, V0, V1, V2, and V3, and the metal conductors in the metal layers M1, M2, M3, and M4 may also be referred to as the frontside IMD layer, the frontside vias, and the frontside metal conductors, respectively. In some embodiments, the vias F_VG are connected to the gate structures (gate electrodes) of the transistors. Therefore, the vias F_VG connected to the gate structures are also referred to as the gate vias, or referred to as the frontside gate vias.

In some embodiments, the vias and metal conductors in the IMD layers 308 and 310 are used for the connections of the features of the transistor. In other embodiments, the vias and metal conductors are connected to voltage sources or power source (the supply voltage VDD (or power source VDD, and VDD power) or the reference voltage VSS (or power source VSS, and VSS power) discussed above) to provide voltage to the transistors in the device region 302. Therefore, the metal conductors (e.g., the metal conductors BM1, BM2) connected to the voltage sources may be also referred to as the voltage metal conductors, the voltage lines, or voltage conductors.

For the operation speed of the SRAM cell is major dominated by transistor on-current and capacitance, in the present disclosure, the metal conductors serving as the bit-lines, the bit-line-bars, the VDD lines, and the VSS lines are designed to be located in the lowest metal layer (i.e., the metal layer M1 in the frontside interconnection structure and the metal layer BM1 in the backside interconnection structure) to have lower capacitance (save metal landing pad capacitance if located at higher metal layers). Furthermore, since the word-lines are more care about resistance, the metal conductors serving as the word-lines are designed to be located in the higher to have larger width for low resistance.

Therefore, in some embodiments, the metal conductors serving as bit-lines and bit-line-bars are designed to be located in the metal layer M1; the metal conductors serving as word-lines are designed to be located in the metal layer M2; and the metal conductors serving as VDD lines and VSS lines are designed to be located in the metal layer BM1.

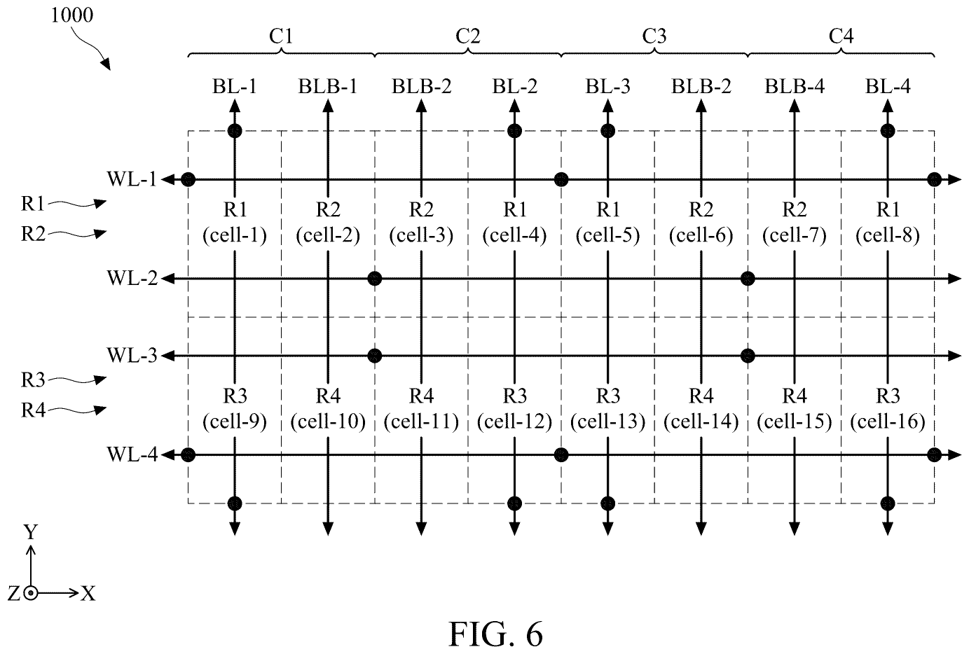

FIG. 6 illustrates a schematic illustration of an array 1000 of SRAM cells (including cell-1 to cell-16) that can be implemented in a memory region of the IC chip in FIG. 1, in accordance with some embodiments of the present disclosure. The array 1000 includes rows R1 to R4 and columns C1 to C4. As shown in FIG. 6, in the array 1000, the row R1 includes the SRAM cells of cell-1, cell-4, cell-5, and cell-8; the row R2 includes the SRAM cells of cell-2, cell-3, cell-6, and cell-7; the row R3 includes the SRAM cells of cell-9, cell-12, cell-13, and cell-16; and the row R4 includes the SRAM cells of cell-10, cell-11, cell-14, and cell-15. The SRAM cells in the adjacent rows in the array are abutted together in the X-direction, as shown in FIG. 6. For example, as shown in FIG. 6, the SRAM cell of cell-1 in the row R1 and the SRAM cell of cell-2 in the row R2 are abutted together in the X-direction. Therefore, each of the columns C1 to C4 of the array 1000 includes pairs of the abutted SRAM cells arranged in the Y-direction, as shown in FIG. 6. For example, as shown in FIG. 6, the column C1 includes a pair of the abutted SRAM cells of cell-1 and cell-2 and a pair of the abutted SRAM cells of cell-9 and cell-10.

The array 1000 further includes word-lines WL-1 to WL-4 extending in the X-direction, and bit-lines BL-1 to BL-4 and bit-line-bars BLB-1 to BLB-4 extending in the Y-direction. As shown in FIG. 6, the two adjacent SRAM cells (i.e., the abutted SRAM cells) in the same column in the array 1000 arranged in the X-direction share one bit-line and one bit-line-bar. For example, the abutted SRAM cells of cell-1 and cell-2 in the same column C1 discussed in above share the bit-line BL-1 and the bit-line-bar BLB-1. As such, the metal conductors serving as bit-lines and bit-line-bars in the array 1000 can be designed with a wider width in enough space, thereby having lower circuit resistance.

FIGS. 7A to 7C illustrate top views (or layouts) of features in a device region, a frontside interconnection structure, and a backside interconnection structure of two adjacent SRAM cells 100A and 100A′ in a portion of an array 1000A in a semiconductor device that can be one embodiment of the SRAM cells in adjacent two rows shown in FIG. 6, in accordance with some embodiments of the present disclosure. FIG. 7A illustrates the features in the device region (including transistors) and the frontside interconnection structure including the metal conductors in the first metal layer (M1), and vias (V0, F_VG) vertically between the features and the first metal layer (M1). FIG. 7B illustrates the frontside interconnection structure including metal conductors in the first metal layer (M1) and the second metal layer (M2), and vias (V1) vertically between the first metal layer (M1) and the second metal layer (M2). FIG. 7C illustrates the backside interconnection structure including the metal conductors in the second metal layer (BM1) and the third metal layer (BM2), and vias (BV1) vertically between the second metal layer (BM1) and the third metal layer (BM2).

FIG. 7D is an X-Z cross-sectional view of the array 1000A in the semiconductor device along a line D-D′ in FIGS. 7A to 7C, in accordance with some embodiments of the present disclosure. FIG. 7E is an X-Z cross-sectional view of the array 1000A in the semiconductor device along a line E-E′ in FIGS. 7A to 7C, in accordance with some embodiments of the present disclosure. FIG. 7F is a Y-Z cross-sectional view of the array 1000A in the semiconductor device along a line F-F′ in FIGS. 7A to 7C, in accordance with some embodiments of the present disclosure. FIG. 7G is a Y-Z cross-sectional view of the array 1000A in the semiconductor device along a line G-G′ in FIGS. 7A to 7C, in accordance with some embodiments of the present disclosure. FIG. 7H is a Y-Z cross-sectional view of the array 1000A in the semiconductor device along a line H-H′ in FIGS. 7A to 7C, in accordance with some embodiments of the present disclosure. FIG. 7I is a Y-Z cross-sectional view of the array 1000A in the semiconductor device along a line I-I′ in FIGS. 7A to 7C, in accordance with some embodiments of the present disclosure.

As shown in FIGS. 7A to 7C, the array 1000A includes the SRAM cells 100A and 100A′ abutted together in the X-direction. In some embodiments, the array 1000A can be one embodiment of a portion of the array 1000 discussed in FIG. 6. The SRAM cells 100A and 100A′ are similar to or the same as the pair of the abutted SRAM cells discussed in FIG. 6, such as the SRAM cells of cell-1 and cell-2. More specifically, the adjacent two SRAM cells 100A and 100A′ are respectively in the adjacent two rows (e.g., the rows R1 and R2 discussed in FIG. 6), and are together in one column (e.g., the column C1 discussed in FIG. 6). In other words, the SRAM cell 100A′ is abutted and adjacent to the SRAM cell 100A in the X-direction, as shown in FIGS. 7A to 7C.

The SRAM cells 100A and 100A′ each respectively has a cell boundary CB and a cell boundary CB′. As shown in FIGS. 7A to 7C, each of the cell boundaries CB and CB′ lengthwise extends in the Y-direction. Furthermore, each of the cell boundaries CB and CB′ has a rectangular shape (indicated by the dotted rectangular box). More specifically, each of the cell boundaries CB and CB′ is rectangular in a top view (or an X-Y plane view), as shown in FIGS. 7A to 7C. Therefore, in some embodiments, the cell boundaries CB and CB′ may be referred to as rectangular cell boundaries. The SRAM cells 100A and 100A′ are abutted together and arranged in the X-direction, such that the cell boundaries CB and CB′ are also abutted together and arranged in the X-direction, as shown in FIGS. 7A to 7C.

The array 1000A includes active areas, such as active areas 402-1 to 402-4, (may be collectively referred to as the active areas 402) that extend lengthwise in the Y-direction and are arranged in the X-direction. The active areas 402-1 and 402-2 are used for the SRAM cell 100A and the active areas 402-3 and 402-4 are used for the SRAM cell 100A′. Each of active areas 402 includes channel regions, source regions, and drain regions (where source regions and drain regions are collectively referred to as source/drain regions herein) of transistors, and portions of the substrate 401 under the channel regions, the source regions, and the drain regions.

The array 1000A further includes gate structures, such as gate structures 404-1 to 404-8 (may be collectively referred to as the gate structures 404) that extend lengthwise in the X-direction. The X-direction and the Y-direction are perpendicular. The gate structures 404-1 to 404-8 are disposed over the channel regions of the respective active areas 402-1 to 402-4 (i.e., (vertically stacked) channel layers 410) and disposed between respective source/drain regions of the active areas 402-1 to 402-4 (i.e., source/drain features 412N and 412P). In some embodiments, the gate structures 404-1 to 404-4 interface at least three surfaces of each of the channel layers 410 in the channel regions of the active areas 402-1 to 402-4. More specifically, the gate structures 404-1 to 404-4 wrap and/or surround suspended, vertically stacked channel layers 410 in the channel regions of the active areas 402-1 to 402-4, respectively (as shown in FIGS. 7D and 7E).

As shown in FIGS. 7A to 7C, in the SRAM cell 100A, the gate structure 404-1 extends across the active area 402-2 in the top view and engages the active area 402-2 to form the pass-gate transistor PG1; the gate structure 404-2 extends across the active areas 402-1 and 402-2 in the top view and engages the active area 402-1 and 402-2 to respectively form the pull-up transistor PU1 and the pull-down transistor PD1; the gate structure 404-3 extends across the active areas 402-1 and 402-2 in the top view and engages the active areas 402-1 and 402-2 to respectively form the pull-up transistor PU2 and the pull-down transistor PD2; and the gate structure 404-4 extends across the active area 402-2 in the top view and engages the active area 402-2 to form the pass-gate transistor PG2.

As shown in FIGS. 7A to 7C, in the SRAM cell 100A′, the gate structure 404-5 extends across the active area 402-4 in the top view and engages the active area 402-4 to form the pass-gate transistor PG1′; the gate structure 404-6 extends across the active areas 402-3 and 402-4 in the top view and engages the active area 402-3 and 402-4 to respectively form the pull-up transistor PU1′ and the pull-down transistor PD1′; the gate structure 404-7 extends across the active areas 402-3 and 402-4 in the top view and engages the active areas 402-3 and 402-4 to respectively form the pull-up transistor PU2′ and the pull-down transistor PD2′; and the gate structure 404-8 extends across the active area 402-4 in the top view and engages the active area 402-4 to form the pass-gate transistor PG2′.

Furthermore, as shown in FIGS. 7A, 7C, 7D, and 7E, the pull-up transistors PU1 and PU2 are arranged in the Y-direction and share the active area 402-1; the pass-gate transistor PG1, the pull-down transistor PD1, the pull-down transistor PD2, and the pass-gate transistor PG2 are arranged in the Y-direction and share the active area 402-2; the pass-gate transistor PG1′, the pull-down transistor PD1′, the pull-down transistor PD2′, and the pass-gate transistor PG2′ are arranged in the Y-direction and share the active area 402-4; and the pull-up transistors PU1′ and PU2′ are arranged in the Y-direction and share the active area 402-3.

In some embodiments, the pull-up transistor PU1 and the pull-down transistor PD1 are arranged in the X-direction and share the gate structure 404-2; the pull-up transistor PU2 and the pull-down transistor PD2 are arranged in the X-direction and share the gate structure 404-3; the pull-up transistor PU1′ and the pull-down transistor PD1′ are arranged in the X-direction and share the gate structure 404-6; and the pull-up transistor PU2′ and the pull-down transistor PD2′ are arranged in the X-direction and share the gate structure 404-7. Therefore, the gate structures 404-2, 404-3, 404-6, and 404-7 are also referred to as common gates or shared gate structures.

Similar to the substrate 202 discussed above, the array 1000A further include a substrate (or a semiconductor substrate) 401, over which the various features are formed, such as the gate structures 404-1 to 404-8. The substrate 401 may contains a semiconductor material, such as bulk silicon (Si). In some other embodiments, the substrate 401 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). Alternatively, the substrate 401 may be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates may be fabricated using separation by implantation of oxygen (SIMOX), wafer bonding, and/or other suitable methods.

In some embodiments, the n-type wells and/or p-type wells are formed in or on the substrate 401. In the present embodiment, the p-type wells are p-type doped regions configured for n-type transistors (e.g., the pass-gate transistors PG1 and PG2, and the pull-down transistors PD1 and PD2), and the n-type well are n-type doped regions configured for p-type transistors (e.g., the pull-up transistors PU1 and PU2). The n-type well is doped with n-type dopants, such as phosphorus, arsenic, other n-type dopant, or a combination thereof. The p-type wells are doped with p-type dopants, such as boron, indium, other p-type dopant, or a combination thereof. In some implementations, the substrate 401 includes doped regions formed with a combination of p-type dopants and n-type dopants. The various n-type wells and/or p-type wells can be formed directly on and/or in the substrate 401, for example, providing a p-well structure, an n-well structure, a dual-well structure, a raised structure, or a combination thereof. An ion implantation process, a diffusion process, and/or other suitable doping process can be performed to form the various wells.

Similar to the isolation feature 218 discussed above, the array 1000A further includes an isolation feature (or isolation structure) 414. The isolation feature 414 is formed between the active areas 402. More specifically, as discussed above, the active areas 402 include the portions of the substrate 401 under the channel regions and the source/drain regions, as shown in FIGS. 7D, 7E, and 7G, and the isolation feature 414 is formed between the portions of the substrate 401. In some aspects, the isolation feature 414 is formed around the active areas 402 (specifically, the portions of the substrate 401 under the channel regions and the source/drain regions). In some embodiments, the gate structures 404 are also formed over and interfacing a top surface of the isolation feature 414. For example, as shown FIGS. 7D and 7E, the gate structures 404-1, 404-2, 404-5, and 404-6 are over and interface a top surface of the isolation feature 414.

The isolation feature 414 may include silicon oxide, silicon nitride, silicon oxynitride, other suitable isolation material (for example, including silicon, oxygen, nitrogen, carbon, or other suitable isolation constituent), or combinations thereof. The isolation feature 414 may include different structures, such as shallow trench isolation (STI) structures, deep trench isolation (DTI) structures, and/or local oxidation of silicon (LOCOS) structures. In some embodiments, STI features include a multi-layer structure that fills the trenches, such as a silicon nitride including layer disposed over a thermal oxide including liner layer. In another example, STI features include a dielectric layer disposed over a doped liner layer (including, for example, boron silicate glass (BSG) or phosphosilicate glass (PSG)). In yet another example, STI features include a bulk dielectric layer disposed over a liner dielectric layer, where the bulk dielectric layer and the liner dielectric layer include materials depending on design requirements.

Each of the transistors in the SRAM cell 100A (e.g., the pass-gate transistors PG1 and PG2, the pull-down transistors PD1 and PD2, and the pull-up transistors PU1 and PU2) and in the SRAM cell 100A′ (e.g., the pass-gate transistors PG1′ and PG2′, the pull-down transistors PD1′ and PD2′, and the pull-up transistors PU1′ and PU2′) includes channel layers 410 in the channel regions of the active area 402, which are similar to the nanostructures 204 discussed above. As shown in FIGS. 7D, 7E, 7H, and 7I, the channel layers 410 are suspended. In some embodiments, three channel layers 410 are vertically stacked (or vertically arranged) from each other in the Z-direction for one transistor. However, there may be another appropriate number of nanostructures in one transistor. For example, there may be from 2 to 6 channel layers 410 in one transistor.

As shown in FIGS. 7A and 7C, a width of the active areas 402-2 and 402-4 in the X-direction is greater than a width of the active areas 402-1 and 402-3. This also means that a channel width of the channel layers 410 in the active areas 402-2 and 402-4 in the X-direction is greater than a channel width of the channel layers 410 in the active areas 402-1 and 402-3, as shown in FIGS. 7D and 7E. The channel layers 410 further extend lengthwise in the Y-direction (FIGS. 7H and 7I) and widthwise in the X-direction (FIGS. 7D and 7E). As shown in FIGS. 7D and 7E, in each of the transistors in the SRAM cells 100A and 100A′, three channel layers 410 are spaced apart from each other in the Z-direction. In some embodiments, the channel layers 410 may also be referred to as channels, nanostructures, nanosheets, or nanowires.

The channel layers 410 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the channel layers 410 include silicon for n-type transistors. In other embodiments, the channel layers 410 include silicon germanium for p-type transistors. In some embodiments, the channel layers 410 are all made of silicon, and the type of the transistors depend on work function metal layer wrapping around the channel layers 410. In some embodiments, the channel layers 410 are epitaxially grown using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized.

Each of the gate structures 404-1 to 404-8 has a gate dielectric layer 406 and a gate electrode layer 408. As discussed above, the gate structures 404 wrap and/or surround the channel layers 410 in the channel regions of the active areas 402-1 to 402-4. More specifically, the gate dielectric layers 406 wrap around each of the channel layers 410, and the gate electrodes layer 408 wrap around the gate dielectric layer 406 and the channel layers 410. In some embodiments, the gate structures 404 each further includes an interfacial layer (such as having silicon dioxide, silicon oxynitride, or other suitable materials) between the gate dielectric layer 406 and the channel layers 410.

The gate dielectric layers 406 may include oxide with nitrogen doped dielectric material (initial layer) combined with metal content high-K dielectric material (K value (dielectric constant)>13). For example, gate dielectric layers 406 may include hafnium oxide (HfO₂), which has a dielectric constant in a range from about 18 to about 40. Alternatively, the gate dielectric layers 406 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba, Sr)TiO₃ (BST), Al₂O₃, Si₃N₄, oxynitrides (SiON), combinations thereof, or other suitable material. The gate dielectric layers 406 may be formed by chemical oxidation, thermal oxidation, ALD, CVD, and/or other suitable methods.

The gate electrode layer 408 is formed to wrap around the gate dielectric layer 406 and the center portions of the channel layers 410, as shown in FIGS. 7H and 7I. In some embodiments, the gate electrode layer 408 may include an n-type work function metal layer 408N for n-type transistor (e.g., the pass-gate transistors PG1, PG2, PG1′, and PG2′, and the pull-down transistors PD1, PD2, PD1′, and PD2′) or a p-type work function metal layer 408P for p-type transistor (e.g., the pull-up transistors PU1, PU2, PU1′, and PU2′).

More specifically, each of the gate electrode layers 408 may have n-type work function metal layers 408N between the source/drain features 412N with an n-type dopant for an n-type transistor (e.g., the pass-gate transistors PG1, PG2, PG1′, and PG2′, and the pull-down transistors PD1, PD2, PD1′, and PD2′) and p-type work function metal layers 408P between the source/drain features 412P with a p-type dopant for a p-type transistor (e.g., the pull-up transistors PU1, PU2, PU1′, and PU2′), in accordance with some embodiments of the present disclosure.

In an embodiment, the n-type work function metal layer 408N is a material such as Ti, Al, Ag, Mn, Zr, TiAl, TiAlC, TaC, TaCN, TaSiN, TaAl, TaAlC, TiAlN, other suitable n-type work function materials, or combinations thereof. For example, the n-type work function metal layer 408N may be deposited utilizing ALD, CVD, or the like. However, any suitable materials and processes may be utilized to form the n-type work function metal layer 408N.

In an embodiment, the p-type work function metal layer 408P is a material such as TiN, TaN, Ru, Mo, Al, WN, ZrSi2, MoSi2, TaSi2, NiSi2, WN, other metal oxides, metal nitrides, metal silicates, transition metal-oxides, transition metal-nitrides, transition metal-silicates, oxynitrides of metals, metal aluminates, zirconium silicate, zirconium aluminate, other suitable p-type work function materials, combinations of these, or the like. Additionally, the p-type work function metal layer 408P may be deposited using a deposition process such as ALD, CVD, or the like, although any suitable deposition process may be used.

In some embodiments, the gate electrode layer 408 may include a single layer or alternatively a multi-layer structure. In some embodiments, the gate electrode layer 408 may further include a capping layer, a barrier layer, and a fill material (not shown). The capping layer may be formed adjacent to the gate dielectric layers 406 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used. The barrier layer may be formed adjacent to the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The SRAM cells 100A and 100A′ further include gate spacers 420 on sidewalls of the gate structures 404 and over the channel layers 410, as shown in FIGS. 7H and 7I. More specifically, the gate spacers 420 are over the channel layers 410 and on top sidewalls of the gate structures 404, and thus are also referred to as gate top spacers or top spacers. Furthermore, the dielectric constant (K value) of the gate spacers 420 is lower than the dielectric constant (K value) of the gate dielectric layers 406. In some embodiments, the thickness of the gate spacers 420 is greater than the thickness of the gate dielectric layers 406.

The gate spacers 420 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 420 may include a single layer or a multi-layer structure.

As shown in FIGS. 7H and 7I, the SRAM cells 100A and 100A′ further include inner spacers 422 on the sidewalls of the gate structures 404 and below the topmost channel layers 410 and the gate spacers 420. Furthermore, the inner spacers 422 are laterally between the source/drain features 412N (or 412P) and the gate structures 404. The inner spacers 422 are also vertically between adjacent channel layers 410. The inner spacers 422 may include a dielectric material having higher K value (dielectric constant) than the gate spacers 420 and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof. In some embodiments, the thickness of the gate spacers 420 in the Y-direction and the thickness of the inner spacers 422 in the Y-direction are the same. In other embodiments, the thickness of the gate spacers 420 in the Y-direction is less than the thickness of the inner spacers 422 in the Y-direction due to the gate spacers 420 are trimmed during processes for forming source/drain contacts.

The SRAM cells 100A and 100A′ further include gate top dielectric layers 416 over the gate dielectric layers 406, the gate electrode layers 408, the channel layers 410, and the gate spacers 420. The gate top dielectric layers 416 are similar to the gate top dielectric layer 214 discussed above. The gate top dielectric layer 416 is used for contact etch protection layer. The material of gate top dielectric layer 416 is selected from a group consisting of oxide, SiOC, SiON, SiOCN, nitride base dielectric, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), combinations thereof, or other suitable material.

As shown in FIGS. 7D to 7G, the SRAM cells 100A and 100A′ further include gate end dielectric structures 418 at ends of the gate structures 404. The gate end dielectric structures 418 are used for separating the gate structures 404 aligned in the X-direction. For example, the gate end dielectrics 418 separate the gate structures 404-2 and 404-6, as shown in FIG. 7D. The gate end dielectric structures 418 are also used for separating the abutted SRAM cells 100A and 100A′ from other device (e.g., SRAM cells or logic cells) in the X-direction. Furthermore, as shown in FIGS. 7D and 7E, the gate end dielectric structure 418 are in contact with and attached to the gate structures 404 in the X-direction. As shown in FIGS. 7D, 7F, and 7G, the gate end dielectric structures 418 further extend into the isolation feature 414 in the Z-direction. In some embodiments, bottom surfaces of the gate end dielectric structures 418 are lower than bottom surfaces of the gate structures 404, as shown in FIGS. 7D and 7E.

The material of the gate end dielectric structures 418 can be single dielectric layer or multiple layers and selected from a group consisting of Si₃N₄, nitride based dielectric layer, SiO₂, SiOC, SiON, SiOCN, carbon content oxide, nitrogen content oxide, carbon and nitrogen content oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y2O3), multiple metal content oxide, or combinations thereof.

Referring to FIGS. 7F to 7I, the SRAM cells 100A and 100A′ further include source/drain features 412N and source/drain features 412P in the source/drain regions of the active areas 402. The source/drain features 412N are disposed on opposite sides of the respective gate structure 404 and connected by the channel layers 410 to form n-type transistor (e.g., the pass-gate transistors PG1, PG2, PG1′, and PG2′, and the pull-down transistors PD1, PD2, PD1′, and PD2′). Similarly, the source/drain features 412P are disposed on opposite sides of the respective gate structure 404 and connected by the channel layers 410 to form p-type transistor (e.g., the pull-up transistors PU1, PU2, PU1′, and PU2′).

In some aspects, the source/drain features 412N/412P are disposed on opposite sides of the respective channel layers 410. More specifically, the source/drain features 412N/412P are attached and electrically connected to the channel layers 410 in the Y-direction, as shown in FIGS. 7H and 7I. In other words, the channel layers 410 are between and attached to the source/drain features 412N/412P in the Y-direction. Therefore, each of the channel layers 410 connect one source/drain feature 412N/412P to the other source/drain feature 412N/412P. Furthermore, every two adjacent transistors in the Y-direction share one source/drain feature 412N/412P, as shown in FIGS. 7H and 7I. In some embodiments, a width of each of the source/drain features 412N/412P in the X-direction is different than a height of each of the source/drain features 412N/412P in the Z-direction, as shown in FIGS. 7F and 7G.

The source/drain features 412N and 412P may be formed by using an epitaxial growth process. In some embodiments, the source/drain features 412N may include epitaxially-grown material selected from a group consisting of SiP, SiC, SiPC, SiAs, Si, or a combination thereof. In some embodiments, the epitaxially-grown material of the source/drain features 412N may be doped with n-type dopants (such as phosphorus, arsenic, other n-type dopant, or combinations thereof) having a doping concentration in a range from about 2×10¹⁹/cm³ to 3×10²¹/cm³. In some embodiments, the source/drain features 412N for n-type transistors may be respectively referred to as n-type features and n-type source/drain features.

In some embodiments, the source/drain features 412P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 412P may be doped with p-type dopants (such as boron, indium, other p-type dopant, or combinations thereof) having a doping concentration in a range from about 1×10¹⁹/cm³ to 6×10²⁰/cm³. In some embodiments, the source/drain features 412P for p-type transistors may be respectively referred to as p-type source/drain features.

Referring to FIGS. 7A to 7I, the SRAM cells 100A and 100A′ further include source/drain contacts 430 (including source/drain contacts 430-1 to 430-9) in an inter-layer dielectric (ILD) layer 426 and source/drain contacts 432 (including source/drain contacts 432-1 to 432-4) in the substrate 401, the isolation feature 414, and an inter-metal dielectric (IMD) layer 610. The ILD layer 426 are formed over the isolation feature 414, as shown in FIGS. 7C and 7E. In some embodiments, the ILD layer 426 surrounds the source/drain contacts 430, and the IMD layer 610 surrounds the source/drain contacts 432. Furthermore, the ILD layer 426, the IMD layer 610, and the isolation feature 414 may have a dielectric constant that is about 3 to about 5. In some embodiments, the ILD layer 426 also fills the spaces between the source/drain features 412N/412P, such that the ILD layer 426 also surrounds the source/drain features 412N/412P.

As shown in FIGS. 7A and 7C, the source/drain contacts 430 and 432 extend lengthwise in the X-direction. The source/drain contacts 430 are self-aligned source/drain contacts. This means that the source/drain contacts 430 are formed by using the gate spacers 420 as a mask. Therefore, the source/drain contacts 430 are in direct contact with and attached to the gate spacers 420, as shown in FIGS. 7H and 7I. In some embodiments, the gate spacers 420 are trimmed due to the gate spacers 420 serving as the mask for forming the source/drain contacts 430. Therefore, the thickness of the gate spacers 420 in the Y-direction is less than the thickness of the inner spacers 422 in the Y-direction, as discussed above.

In the top view, as shown in FIG. 7A, the source/drain contact 430-4 overlaps the cell boundary CB, the source/drain contact 430-6 lengthwise overlaps the cell boundary CB′, and the source/drain contacts 430-1, 430-5, and 430-9 overlap the cell boundaries CB and CB′. In the top view, as shown in FIG. 7C, the source/drain contacts 432-1, 432-2, 432-3, and 432-4 respectively overlap the active areas 402-1, 402-2, 402-3, and 402-4.

In the top view, as shown in FIG. 7A, the source/drain contact 430-1 is adjacent to the gate structure 404-1 and 404-5 (or is adjacent to the pass-gate transistors PG1 and PG1′) in the Y-direction; the source/drain contact 430-2 is between the gate structures 404-1 and 404-2 (or between the pass-gate transistor PG1 and the pull-down transistor PD1) in the Y-direction; the source/drain contact 430-3 is between the gate structures 404-2 and 404-6 (or between the pass-gate transistor PG1′ and the pull-down transistor PD1′) in the Y-direction; the source/drain contact 430-4 is between the gate structures 404-2 and 404-3 (or between the pull-up transistors PU1 and PU2) in the Y-direction; the source/drain contact 430-5 is between the gate structures 404-2 and 404-3 (or between the pull-down transistors PD1 and PD2) and between the gate structures 404-6 and 404-7 (or between the pull-down transistors PD1′ and PD2′) in the Y-direction; the source/drain contact 430-6 is between the gate structures 404-6 and 404-7 (or between the pull-up transistors PU1′ and PU2′) in the Y-direction; the source/drain contact 430-7 is between the gate structures 404-3 and 404-4 (or between the pass-gate transistor PG2 and the pull-down transistor PD2) in the Y-direction; the source/drain contact 430-8 is between the gate structures 404-7 and 404-8 (or between the pass-gate transistor PG2′ and the pull-down transistor PD2′) in the Y-direction; and the source/drain contact 430-9 is adjacent to the gate structure 404-4 and 404-8 (or is adjacent to the pass-gate transistors PG2 and PG2′) in the Y-direction.

In the top view, as shown in FIG. 7C, the source/drain contact 432-1 is between the gate structures 404-2 and 404-3 (or between the pull-up transistors PU1 and PU2) in the Y-direction; the source/drain contact 432-2 is between the gate structures 404-2 and 404-3 (or between the pull-down transistors PD1 and PD2) in the Y-direction; the source/drain contact 432-3 is between the gate structures 404-6 and 404-7 (or between the pull-down transistors PD1′ and PD2′) in the Y-direction; and the source/drain contact 432-4 is between the gate structures 404-6 and 404-7 (or between the pull-up transistors PU1′ and PU2′) in the Y-direction.

Furthermore, each of the source/drain contacts 430 is over and electrically connected to the respective source/drain features 412N/412P and each of the source/drain contacts 432 is under electrically connected to the respective source/drain features 412N/412P. Specifically, as shown in FIGS. 7A and 7F to 7I, the source/drain contact 430-1 is over and electrically connected to the source/drain features 412N of the pass-gate transistors PG1 and PG1′; the source/drain contact 430-2 is over and electrically connected to the source/drain feature 412N shared by the pass-gate transistor PG1 and the pull-down transistor PD1 ((also referred to as common source/drain or common drain (CD1)) and the source/drain feature 412P of the pull-up transistor PU1, which corresponds to the storage node SN shown in FIG. 2; the source/drain contact 430-3 is over and electrically connected to the source/drain feature 412N shared by the pass-gate transistor PG1′ and the pull-down transistor PD1′ ((also referred to as common source/drain or common drain (CD1)) and the source/drain feature 412P of the pull-up transistor PU1′, which corresponds to the storage node SN shown in FIG. 2; the source/drain contact 430-4 is over and electrically connected to the source/drain feature 412P shared by the pull-up transistors PU1 and PU2; the source/drain contact 430-5 is over and electrically connected to the source/drain feature 412N shared by the pull-down transistors PD1 and PD2 and the source/drain feature 412N shared by the pull-down transistors PD1′ and PD2′; the source/drain contact 430-6 is over and electrically connected to the source/drain feature 412P shared by the pull-up transistors PU1′ and PU2′; the source/drain contact 430-7 is over and electrically connected to the source/drain feature 412N shared by the pass-gate transistor PG2 and the pull-down transistor PD2 (also referred to as common source/drain or common drain (CD2)) and the source/drain feature 412P of the pull-up transistor PU2, which corresponds to the storage node SNB shown in FIG. 2; the source/drain contact 430-8 is over and electrically connected to the source/drain feature 412N shared by the pass-gate transistor PG2′ and the pull-down transistor PD2′ (also referred to as common source/drain or common drain (CD2)) and the source/drain feature 412P of the pull-up transistor PU2′, which corresponds to the storage node SNB shown in FIG. 2; and the source/drain contact 430-9 is over and electrically connected to the source/drain features 412N of the pass-gate transistors PG2 and PG2′.

As shown in FIGS. 7C and 7F to 7I, the source/drain contact 432-1 is under and electrically connected to the source/drain feature 412P shared by the pull-up transistors PU1 and PU2; the source/drain contact 432-2 is under and electrically connected to the source/drain feature 412N shared by the pull-down transistors PD1 and PD2; the source/drain contact 432-3 is under and electrically connected to the source/drain feature 412N shared by the pull-down transistors PD1′ and PD2′; and the source/drain contact 432-4 is under and electrically connected to the source/drain feature 412P shared by the pull-up transistors PU1′ and PU2′.

In some embodiments, the source/drain contacts 430 may be referred to as frontside source/drain contacts due to the source/drain contacts 430 are over the source/drain features 412N/412P (i.e., over the device region including the features of the transistors discussed above). In some embodiments, the source/drain contacts 432 may be referred to as backside source/drain contacts due to the source/drain contacts 432 are under the source/drain features 412N/412P (i.e., under the device region including the features of the transistors discussed above).

The source/drain contacts 430 and 432 may each include a conductive material such as Al, Cu, W, Co, Ti, Ta, Ru, Rh, Ir, Pt, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 430 and 432 may each include single conductive material layer or multiple conductive layers.

As shown in FIGS. 7F to 7I, the SRAM cells 100A and 100A′ further include silicide features 424 over or under the source/drain features 412N and 412P. More specifically, the silicide features 424 are formed between the source/drain contacts 430 and the source/drain features 412N/412P and/or between the source/drain contacts 432 and the source/drain features 412N/412P. The conductivity of the silicide features 424 is greater than the conductivity of the source/drain features 412N/412P. In some embodiments, the conductivity of the source/drain contacts 430 and 432 is greater than the conductivities of the silicide features 424 and the source/drain features 412N/412P.

The silicide features 424 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

As discussed above, the frontside interconnection structure is over the device region or at the frontside of the device region. As shown in FIGS. 7A to 7I, the array 1000A further include a frontside interconnection structure 502 having gate vias 504 (including gate vias 504-1 to 504-8), vias 506 (including vias 506-1 to 506-5), metal conductors 508 (including metal conductors 508-1 to 508-9), vias 510 (including vias 510-1 and 510-2), metal conductors 512 (including metal conductors 512-1 and 512-2), an ILD layer 514, and an inter-metal dielectric (IMD) layer 516, which are over (or at the frontside of) the transistors in the SRAM cells 100A and 100A′ (e.g., the pass-gate transistors PG1, PG2, PG1′, and PG2′, the pull-down transistors PD1, PD2, PD1′, and PD2′, and the pull-up transistors PU1, PU2, PU1′, and PU2′).

The gate vias 504 and vias 506 are in the ILD layer 514. The vias 510 and metal conductors 508 and 512 are in the IMD layer 516. The metal conductors 508 and 512 are respectively in the (frontside) metal layers M1 and M2, as discussed above. The metal layer M1 is over the device region of the SRAM cells 100A and 100A′ (specifically, the transistor and the features thereof in the SRAM cells 100A and 100A′) and the metal layer M2 is over the metal layer M1, and thus the metal conductors 508 are over the transistors (e.g., the pass-gate transistors PG1, PG2, PG1′, and PG2′, the pull-down transistors PD1, PD2, PD1′, and PD2′, and the pull-up transistors PU1, PU2, PU1′, and PU2′) and features (including the source/drain contacts 430, the source/drain features 412N/412P, the channel layers 410, and gate structures 404) of the SRAM cells 100A and 100A′, and the metal conductors 512 are over the metal conductors 508. As show in FIGS. 7A and 7B, the metal conductors 508 extend lengthwise in the Y-direction, and the metal conductors 512 extend lengthwise in the X-direction.

Each of the gate vias 504 is vertically between and electrically connected to the respective gate structure 404 and the respective metal conductor 508. Each of the vias 506 is vertically between and electrically connected to the respective source/drain contact 430 and the respective metal conductor 508. Each of the vias 510 is vertically between and electrically connected to the respective metal conductor 508 and the respective metal conductor 512. In some embodiments, the gate vias 504, the vias 506 and 510 may have a square shape in the top view. In other embodiments, the gate vias 504, the vias 506 and 510 may have a circular shape in the top view.

The gate vias 504, the vias 506, and the vias 510 may be respectively similar to the via F_VG, the via V0, and the vias V1 discussed above. The gate vias 504, the vias 506, the vias 510, the metal conductors 508 and 512, the ILD layer 514, and the IMD layer 516 may also be referred to as frontside gate vias, frontside vias, frontside metal conductors, frontside ILD layer, and frontside IMD layer, respectively.

As discussed above, connections of the SRAM cells 100A and 100A′ correspond to the circuit of the SRAM cell 100 shown in FIG. 2. In some embodiments, the metal conductors 508-2 and 508-7 serve as storage node SN as discussed above, and the metal conductors 508-3 and 508-8 serve as storage node SNB as discussed above. In the top view, as shown in FIG. 7A, the metal conductor 508-2 is over and across the gate structures 404-2 and 404-3 and the source/drain contact 430-2; the metal conductor 508-3 is over and across the gate structures 404-2 and 404-3 and the source/drain contact 430-7; the metal conductor 508-7 is over and across the gate structures 404-6 and 404-7 and the source/drain contact 430-3; and the metal conductor 508-8 is over and across the gate structures 404-6 and 404-7 and the source/drain contact 430-8.

As shown in FIG. 7A, for the SRAM cell 100A, the metal conductor 508-2 is electrically connected to the source/drain contact 430-2 (thus also electrically connected to the source/drain feature 412N shared by the pass-gate transistor PG1 and the pull-down transistor PD1 and the source/drain feature 412P of the pull-up transistor PU1) through the via 506-1 and the gate structure 404-3 through the gate via 504-3; the metal conductor 508-3 is electrically connected to the source/drain contact 430-7 (thus also electrically connected to the source/drain feature 412N shared by the pass-gate transistor PG2 and the pull-down transistor PD2 and the source/drain feature 412P of the pull-up transistor PU2) through the via 506-2 and the gate structure 404-2 through the gate via 504-4.

For the SRAM cell 100A′, the metal conductor 508-7 is electrically connected to the source/drain contact 430-3 (thus also electrically connected to the source/drain feature 412N shared by the pass-gate transistor PG1′ and the pull-down transistor PD1′ and the source/drain feature 412P of the pull-up transistor PU1′) through the via 506-6 and the gate structure 404-7 through the gate via 504-5; the metal conductor 508-8 is electrically connected to the source/drain contact 430-8 (thus also electrically connected to the source/drain feature 412N shared by the pass-gate transistor PG2′ and the pull-down transistor PD2′ and the source/drain feature 412P of the pull-up transistor PU2′) through the via 506-7 and the gate structure 404-6 through the gate via 504-6.

Since the metal conductor 508-2 is connected to the source/drain contact 430-4 that corresponds to the storage node SN, the metal conductor 508-7 is connected to the source/drain contact 430-3 that corresponds to the storage node SN, the metal conductor 508-3 is connected to the source/drain contact 430-7 that corresponds to the storage node SNB, and the metal conductor 508-8 is connected to the source/drain contact 430-8 that corresponds to the storage node SNB, the metal conductors 508-2, 508-7, 508-3 and 508-8 may also be referred to as data node lines, data node conductors, storage node lines, and the storage node conductors. In some embodiments, the metal conductors 508-2, 508-7, 508-3 and 508-8 may also be referred to as local connection lines or local connection conductors.

As discussed in FIG. 6, the abutted SRAM cells in the adjacent two rows and in the same column share the bit-line and the bit-line-bar. In some embodiments, the metal conductors 508-4 and 508-6 respectively serve as the bit-line BL and the bit-line-bar BLB discussed above that shared by the SRAM cells 100A and 100A′. In other words, the metal conductors 508-4 and 508-6 respectively serving as the bit-line BL and the bit-line-bar BLB are electrically connected to the SRAM cells 100A and 100A′. More specifically, the metal conductor 508-4 serving as the bit-line BL is shared by the pass-gate transistor PG1 in the SRAM cell 100A and the pass-gate transistor PG1′ in the SRAM cell 100A′, and the metal conductor 508-6 serving as the bit-line-bar BLB is shared by the pass-gate transistor PG2 in the SRAM cell 100A and the pass-gate transistor PG2′ in the SRAM cell 100A′.

As shown in FIGS. 7A to 7I, for the SRAM cell 100A, the metal conductor 508-4 is electrically connected to the source/drain feature 412N of the pass-gate transistor PG1 through the via 506-3 and the source/drain contact 430-1; and the metal conductor 508-6 is electrically connected to the source/drain feature 412N of the pass-gate transistor PG2 through the via 506-5 and the source/drain contact 430-9.

Similarly, for the SRAM cell 100A′, the metal conductor 508-4 is also electrically connected to the source/drain feature 412N of the pass-gate transistor PG1′ through the via 506-3 and the source/drain contact 430-1; and the metal conductor 508-6 is also electrically connected to the source/drain feature 412N of the pass-gate transistor PG2′ through the via 506-5 and the source/drain contact 430-9.

As shown in FIG. 7A, in the top view, the via 506-3 overlaps the cell boundary CB, and the via 506-5 overlap the cell boundary CB′. Furthermore, the metal conductor 508-4 extends in the Y-direction and crosses the cell boundary CB, and the metal conductor 508-6 extends in the Y-direction and crosses the cell boundary CB′. In some embodiments, the metal conductor 508-4 may be referred to as (frontside) bit-line conductor, and the metal conductor 508-6 may be referred to as (frontside) bit-line-bar conductor.

In some embodiments, the metal conductor 508-5 serve as VSS line that is electrically coupled to a voltage source (not shown) (e.g., the reference voltage VSS discussed above), and shared by the SRAM cells 100A and 100A′. In other words, the metal conductor 508-5 serving as the VSS line is electrically connected to the SRAM cells 100A and 100A′. More specifically, the metal conductor 508-5 serving as the VSS line is shared by the pull-down transistors PD1 and PD2 in the SRAM cell 100A and the pull-down transistors PD1′ and PD2′ in the SRAM cell 100A′.

As shown in FIG. 7A to 7I, the metal conductor 508-5 is electrically connected to the source/drain feature 412N shared by the pull-down transistors PD1 and PD2 in the SRAM cell 100A and the source/drain feature 412N shared by the pull-down transistor PD1′ and PD2′ in the SRAM cell 100A through the via 506-4 and the source/drain contact 430-5.

As shown in FIG. 7A, in the top view, the via 506-4 overlaps the cell boundaries CB and CB′. Furthermore, in the top view, the metal conductor 508-5 lengthwise overlap the cell boundaries CB and CB′. In some embodiments, the metal conductor 508-5 serving as the VSS line is between the metal conductor 508-4 serving as the bit-line and the metal conductor 508-6 serving as the bit-line-bar in the X-direction. In some aspects, the metal conductor 508-4 serving as the bit-line and the metal conductor 508-6 serving as the bit-line-bar are disposed on opposite sides of the metal conductor 508-5 in the X-direction. In some embodiments, metal conductor 508-5 may be referred to as (frontside) VSS conductors or (frontside) VSS lines.

In some embodiments, the metal conductors 512-1 and 512-2 respectively serve as the word-lines WL discussed above that controls and electrically connected to the SRAM cells 100A and 100A′. More specifically, the metal conductor 512-1 serving as the word-line WL is electrically connected to the pass-gate transistors PG1 and PG2 in the SRAM cell 100A, and the metal conductor 512-2 serving as the word-line WL is electrically connected to the pass-gate transistors PG1′ and PG2′ in the SRAM cell 100A′.

As shown in FIGS. 7A to 7I, for the SRAM cell 100A, the metal conductor 512-1 is electrically connected to the gate structure 404-1 of the pass-gate transistor PG1 through the via 510-1, the metal conductor 508-1, and the gate via 504-1, and is electrically connected to the gate structure 404-4 of the pass-gate transistor PG2 through the via 510-1, the metal conductor 508-1, and the gate via 504-2.

Similarly, for the SRAM cell 100A′, the metal conductor 512-2 is electrically connected to the gate structure 404-5 of the pass-gate transistor PG1′ through the via 510-2, the metal conductor 508-9, and the gate via 504-7, and is electrically connected to the gate structure 404-8 of the pass-gate transistor PG2′ through the via 510-2, the metal conductor 508-9, and the gate via 504-8.

As shown in FIGS. 7A and 7B, in the top view, the via 510-1, the gate vias 504-1 and 504-2 overlap the cell boundary CB, and the via 510-2, the gate vias 504-7 and 504-8 overlap the cell boundary CB′. Furthermore, in the top view, the metal conductor 508-1 lengthwise overlaps the cell boundary CB, and the metal conductor 508-9 lengthwise overlaps the cell boundary CB′. In some embodiments, the metal conductors 512-1 and 512-2 may be referred to as (frontside) word-line conductors. In some embodiments, the metal conductors 508-1 and 508-9 may be referred to as write word-line landing pads.

As discussed above, the backside interconnection structure is under the device region or at the backside of the device region. As shown in FIGS. 7A to 7I, the array 1000A further include a backside interconnection structure 602 having metal conductors 604 (including metal conductors 604-1 to 604-3), a via 606, a metal conductor 608, and an inter-metal dielectric (IMD) layer 610, which are under (or at the backside of) the transistors in the SRAM cells 100A and 100A′ (e.g., the pass-gate transistors PG1, PG2, PG1′, and PG2′, the pull-down transistors PD1, PD2, PD1′, and PD2′, and the pull-up transistors PU1, PU2, PU1′, and PU2′).

The metal conductors 604, via 606, and the metal conductor 608 are in the IMD layer 610. The metal conductors 604 and 608 are respectively in the (backside) metal layers BM1 and BM2, as discussed above. The metal layer BM1 is under the device region of the SRAM cells 100A and 100A′ (specifically, the transistor and the features thereof in the SRAM cells 100A and 100A′) and the metal layer BM2 is under the metal layer BM1, and thus the metal conductors 604 are under the transistors (e.g., he pass-gate transistors PG1, PG2, PG1′, and PG2′, the pull-down transistors PD1, PD2, PD1′, and PD2′, and the pull-up transistors PU1, PU2, PU1′, and PU2′) and features (including the source/drain contacts 430, the source/drain features 412N/412P, the channel layers 410, and gate structures 404) of the SRAM cells 100A and 100A′, and the metal conductor 608 is under the metal conductors 604. As show in FIG. 7C, the metal conductors 604 extend lengthwise in the Y-direction, and the metal conductor 608 extends lengthwise in the X-direction.

Each of the source/drain contact 432 is vertically between and electrically connected to the respective source/drain features 412N/412P and the respective metal conductor 604. The via 606 is vertically between and electrically connected to the metal conductors 604-2 and the metal conductor 608. In some embodiments, the via 606 may have a square shape in the top view. In other embodiments, the via 606 may have a circular shape in the top view.

The via 606 may be respectively similar to the vias BV1 discussed above. The via 606, the metal conductors 604 and 608, and the IMD layer 610 may also be referred to as backside vias, backside metal conductors, and backside IMD layer, respectively.

In some embodiments, the metal conductors 604-1 and 604-3 serves as VDD lines that are electrically coupled to a voltage source (not shown) (e.g., the supply voltage VDD discussed above) and electrically connected to the SRAM cells 100A and 100A′. More specifically, the metal conductor 604-1 serving as the VDD line is electrically connected to the pull-up transistors PU1 and PU2 in the SRAM cell 100A, and the metal conductor 604-3 serving as the VDD line is electrically connected to the pull-up transistors PU1′ and PU2′ in the SRAM cell 100A′.

As shown in FIGS. 7C to 7I, for the SRAM cell 100A, the metal conductor 604-1 is electrically connected to the source/drain feature 412P shared by the pull-up transistors PU1 and PU2 through the source/drain contact 432-1.

Similarly, for the SRAM cell 100A′, the metal conductor 604-3 is electrically connected to the source/drain feature 412P shared by the pull-up transistors PU1′ and PU2′ through the source/drain contact 432-4.

As shown in FIG. 7C, in the top view, the metal conductor 604-1 lengthwise overlaps the cell boundary CB and the active area 402-1, and the metal conductor 604-3 lengthwise overlaps the cell boundary CB′ and the active area 402-3. In some embodiments, the metal conductors 604-1 and 604-3 may be referred to as (frontside) VDD conductors or (frontside) VDD lines.

The metal conductors 604-2 and 608 serve as VSS lines that are coupled together, electrically coupled to a voltage source (not shown) (e.g., the reference voltage VSS discussed above), and shared by the SRAM cells 100A and 100A′. In other words, the metal conductors 604-2 and 608 serving as the VSS lines are electrically connected to the SRAM cells 100A and 100A′. More specifically, metal conductors 604-2 and 608 serving as the VSS lines are shared by the pull-down transistors PD1 and PD2 in the SRAM cell 100A and the pull-down transistors PD1′ and PD2′ in the SRAM cell 100A′.

As shown in FIGS. 7C to 7I, the metal conductor 604-2 is electrically connected to the source/drain feature 412N shared by the pull-down transistors PD1 and PD2 through the source/drain contact 432-2 and is electrically connected to the source/drain feature 412N shared by the pull-down transistor PD1′ and PD2′ through the source/drain contact 432-3, and the metal conductor 608 is electrically connected to the metal conductor 604-2 through the via 606. As such, the metal conductors 604-2 and 608 may construct a power mesh to supply the reference voltage VSS to the pull-down transistors. The metal conductors 604-2 and 608 may also be seen to be electrically connected with each other in parallel, such that the total resistance of the metal conductors 604-2 and 608 are reduced, thereby improving the performance of the array 1000A.

As shown in FIG. 7C, in the top view, the via 510-1, the via 606 overlaps the cell boundaries CB and CB′. Furthermore, in the top view, the metal conductor 604-2 lengthwise overlaps the cell boundaries CB and CB′ and the active areas 402-2 and 402-4. In some embodiments, the metal conductors 604-2 and 608 may be referred to as (backside) VSS conductors or (backside) VSS lines.

The ILD layer 426, the ILD layer 514, the IMD layer 516, and the IMD layer 610 each may include one or more dielectric layers including dielectric materials, such as tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or a combination thereof.

The materials of the gate vias 504, the vias 506, the metal conductors 508, the vias 510, the metal conductors 512, the metal conductors 604, the via 606, and the metal conductor 608 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

As shown in FIGS. 7A to 7I, the metal conductors 604-1 and 604-3 serving as VDD lines and the metal conductors 604-2 and 608 serving as VSS lines are disposed at the backside of the device region of the SRAM cells 100A and 100A′. Therefore, the metal conductors 604 and 608 may construct and be referred to as backside power delivery network (BSPDN) to supply power to the SRAM cells 100A and 100A′ (specifically, the array 1000A). In some embodiments, the metal conductors 604-1 and 604-3 serving as VDD lines and the metal conductors 604-2 and 608 serving as VSS lines may also be referred to as (backside) power conductors.

As shown in FIGS. 7A to 7I, the metal conductors 512-1 and 512-2 serving as the word-line WL are more concerned about the resistance, so that metal conductors 512-1 and 512-2 may be disposed at the higher metal layer to have more space, thereby it may be designed with wider width to reduce the resistance. In some embodiments, the widths of the metal conductors 512-1 and 512-2 in the Y-direction are greater than the widths of the metal conductors 508 in the X-direction, as shown in FIGS. 7A to 7C.

The metal conductors 508-4 and 508-6 respectively serving as the bit-line BL and the bit-line-bar BLB are more concerned about the capacitance, so that the metal conductors 508-4 and 508-6 are preferred to put in lowest level metallization layer in the frontside interconnection structure (e.g., the metal layer M1 discussed above) for bit-line capacitance reduction to have lower capacitance, thereby improving the performance of the semiconductor devices.

The metal conductors 604 serving as the VDD lines and the VSS lines are in the lowest level metallization layer in the backside interconnection structure (e.g., the metal layer BM1 discussed above) to have lower capacitance. Furthermore, this is also means that the crowded space at the frontside interconnection structure in existing technologies are relieved to reduce the routing complexity of the SRAM cells. The metal conductors 604 serving as the VDD lines and the VSS lines may also be designed with wider width to reduce the resistance due to the broad space at the backside interconnection structure. As shown in FIGS. 7A to 7C, the widths of the metal conductors 604 in the X-direction are greater than the widths of the metal conductors 508 in the X-direction.

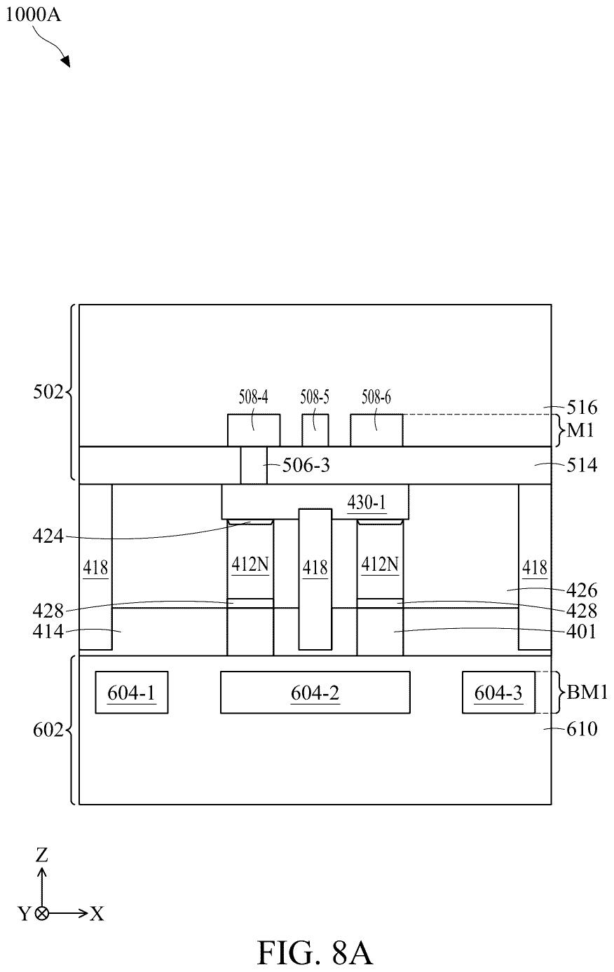

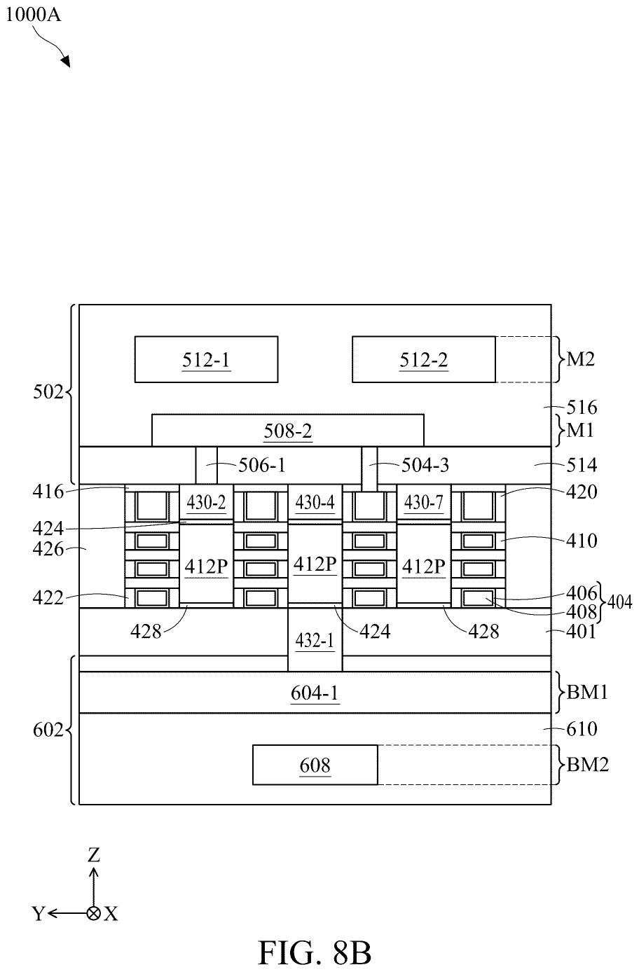

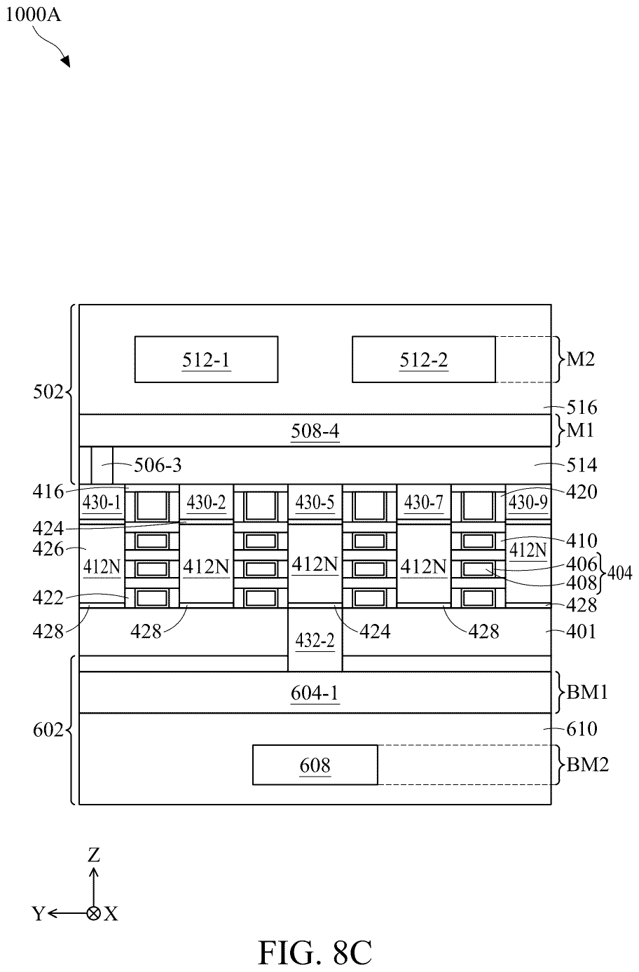

FIG. 8A is a Y-Z cross-sectional view of the array 1000A in the semiconductor device along a line G-G′ in FIGS. 7A to 7C, in accordance with some alternative embodiments of the present disclosure. FIG. 8B is a Y-Z cross-sectional view of the array 1000A in the semiconductor device along a line H-H′ in FIGS. 7A to 7C, in accordance with some alternative embodiments of the present disclosure. FIG. 8C is a Y-Z cross-sectional view of the array 1000A in the semiconductor device along a line I-I′ in FIGS. 7A to 7C, in accordance with some alternative embodiments of the present disclosure.

Referring back to FIGS. 7G to 7I, the source/drain features 412N and 412P not electrically connected to the source/drain contact 432 are formed over and attached to the substrate 401. In some embodiments, the array 1000A shown in FIGS. 8A to 8C further includes bottom dielectric layers 428 under the source/drain features 412N and 412P not electrically connected to the source/drain contact 432 and over the substrate 401. In some embodiment, the bottom dielectric layer 428 is in contact with and attached to the sidewalls of the inner spacers 422, in the Y-Z cross-sectional view, as shown in FIGS. 8B and 8C. In some aspect, the bottom dielectric layers 428 are between the inner spacers 422, in the Y-Z cross-sectional view. The bottom dielectric layers 428 are formed before the formation of the source/drain features 412N and 412P. More specifically, after the formation of the inner spacers 422, the bottom dielectric layers 428 are formed in source/drain trenches for the source/drain features 412N and 412P and over the substrate 401, and the source/drain features 412N and 412P are then formed over the bottom dielectric layers 428.

In some embodiments, the dielectric material of the bottom dielectric layer 428 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), other suitable material(s), or a combination thereof, and may be deposited by CVD, PVD, ALD, HDPCVD, MOCVD, RPCVD, PECVD, LPCVD, ALCVD, APCVD, other suitable methods, or a combination thereof.

It should be noted that the source/drain features 412N and 412P are separated from the substrate 401 by the bottom dielectric layers 428, as shown in FIGS. 8A to 8C. As such, it prevents the leakage current of the resultant transistors from one source/drain feature 412N/412P to another source/drain feature 412N/412P through the substrate 401, thereby improving performances of the resultant transistors.

In some alternative embodiments, the bottom dielectric layers 428 are formed under the source/drain features 412N not electrically connected to the source/drain contact 432 (as shown in FIG. 8C) and the source/drain features 412P not electrically connected to the source/drain contact 432 are formed in contact with and attached to the substrate 401 (as shown in FIG. 7H). Therefore, each of the source/drain features 412P not electrically connected to the source/drain contact 432 has a larger volume than the source/drain features 412N not electrically connected to the source/drain contact 432 to keep strain for channel layers 410 in the P-type transistor (e.g., the pull-up transistors PU1, PU2, PU1′, and PU2′), thereby improving the performance of the P-type transistor in the array 1000A.

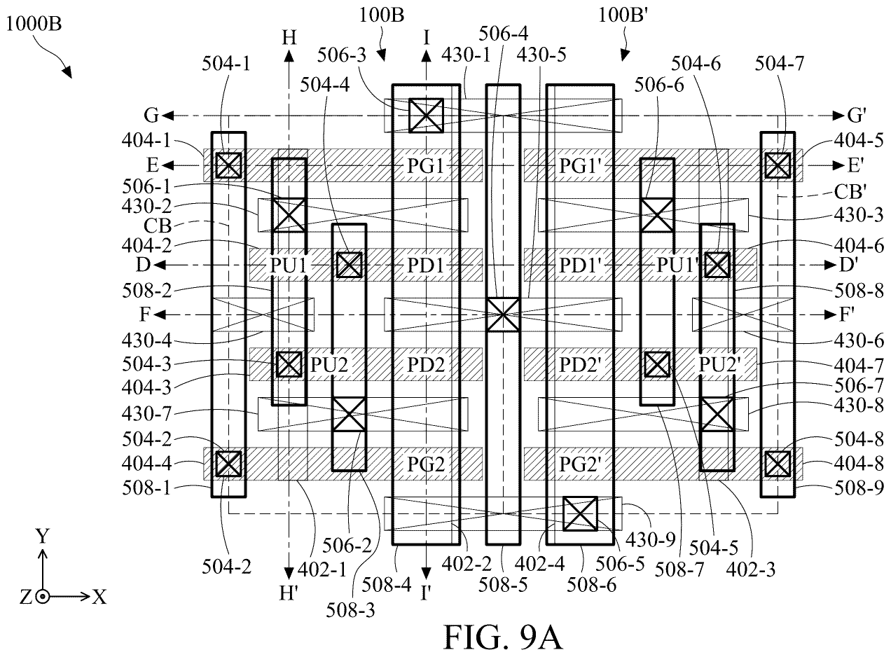

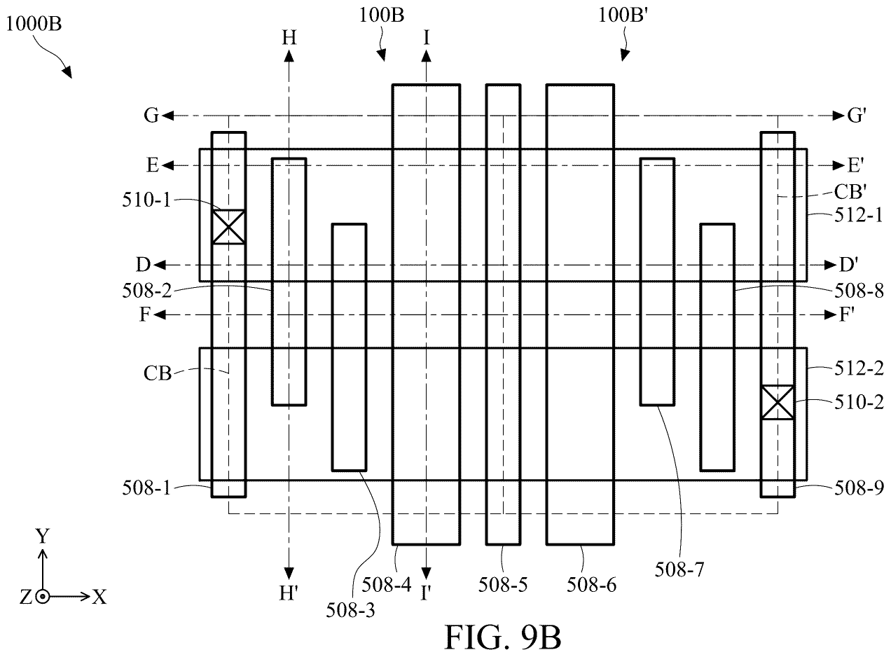

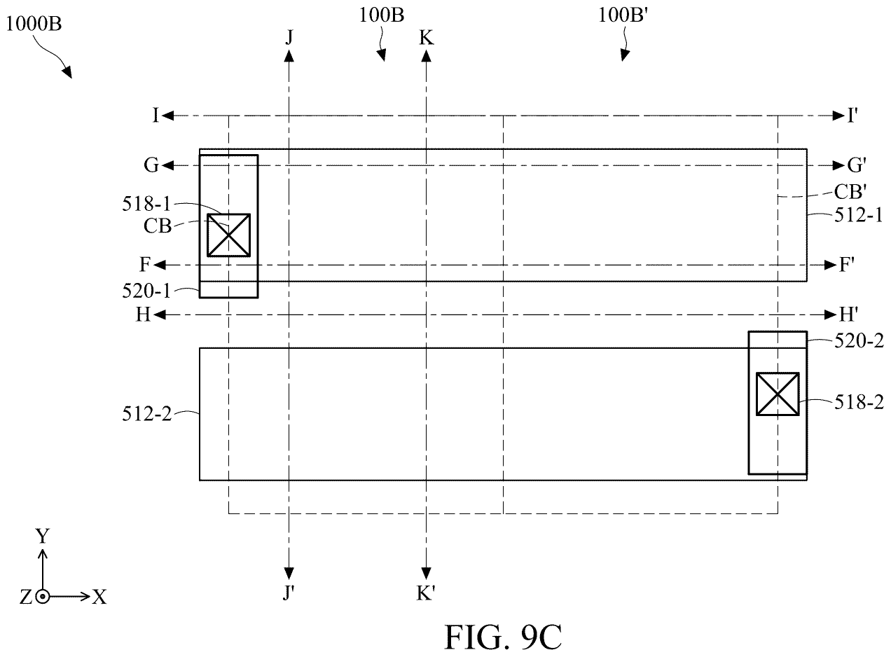

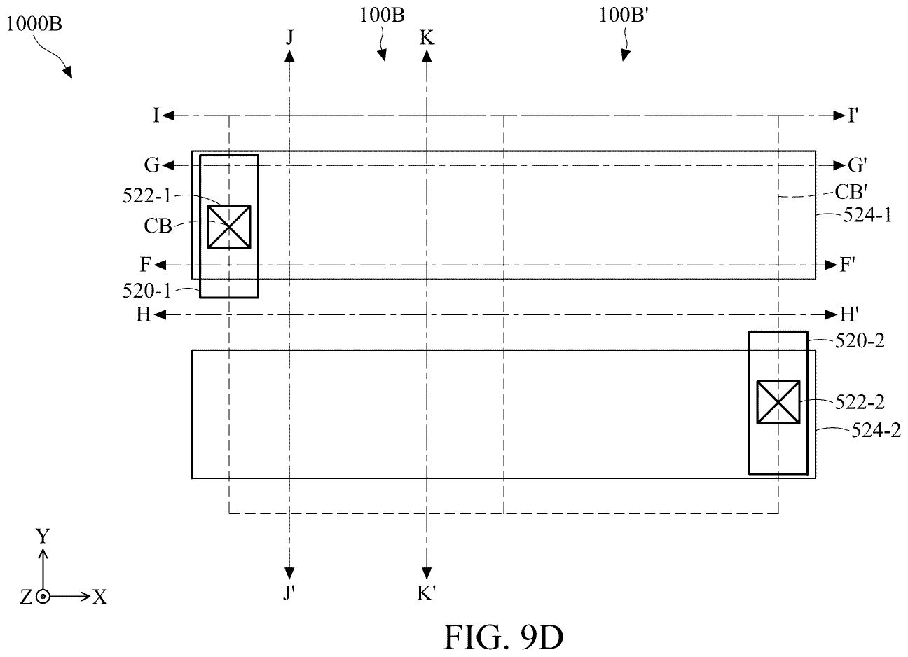

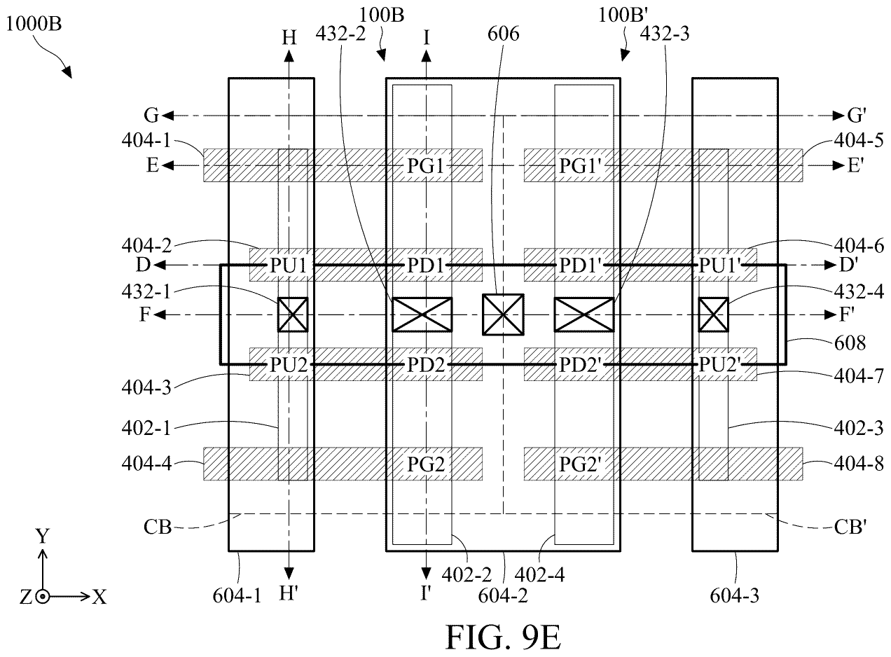

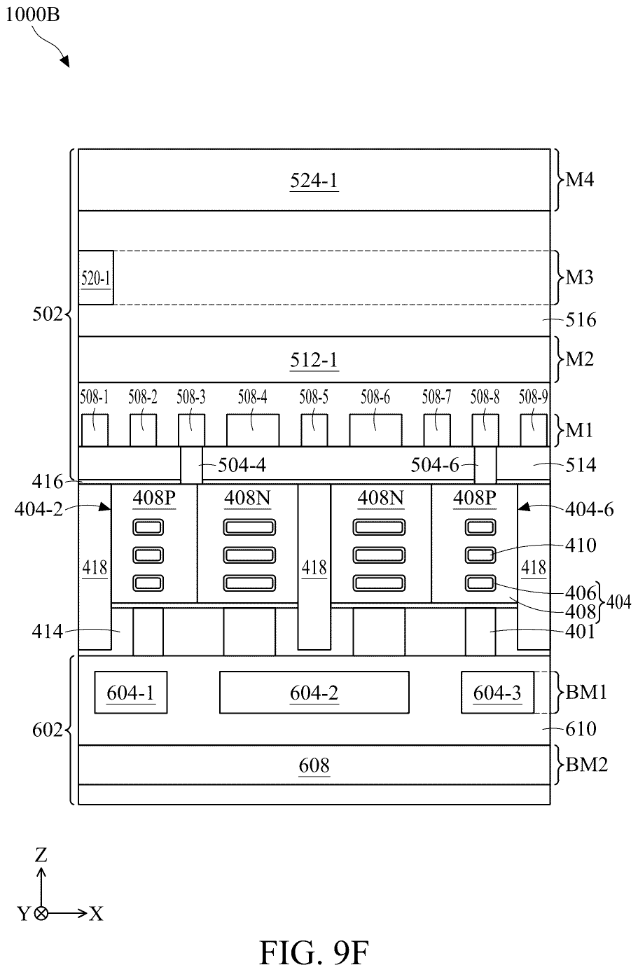

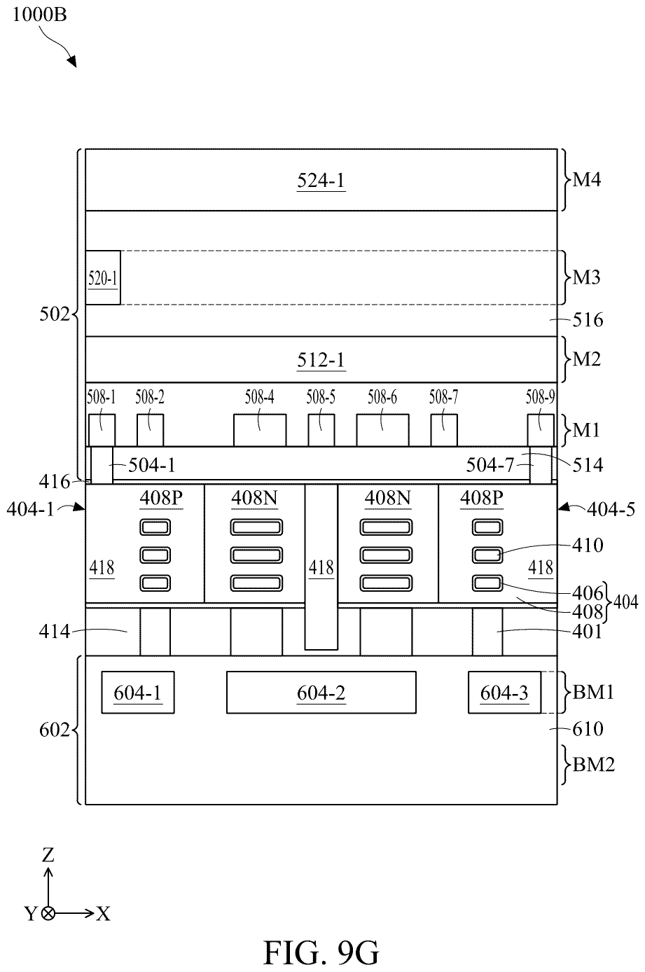

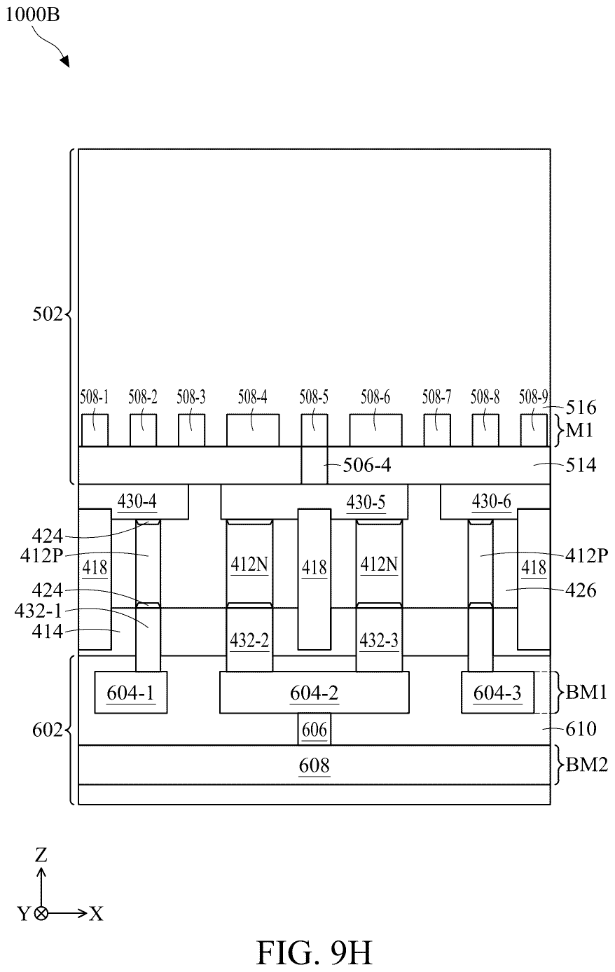

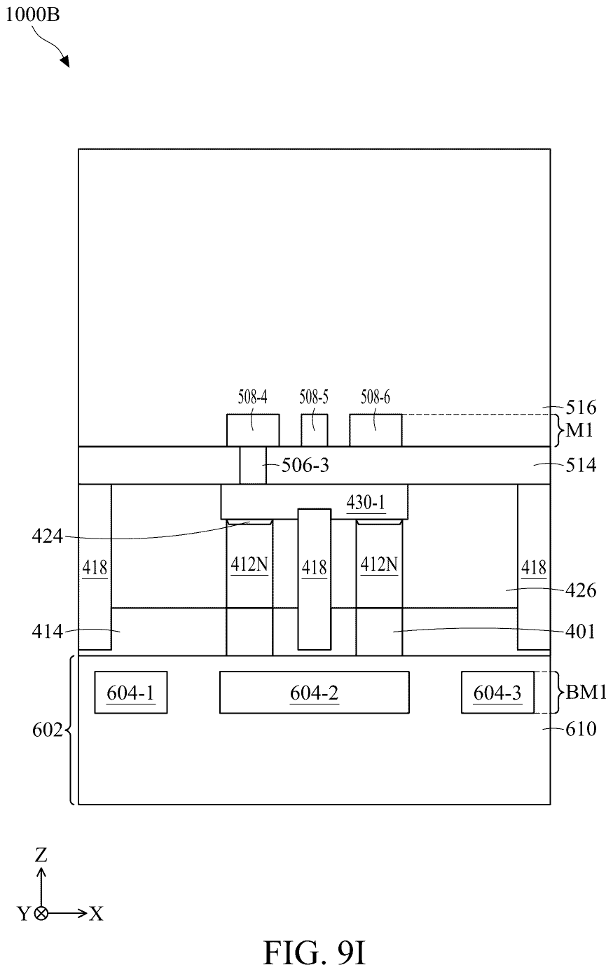

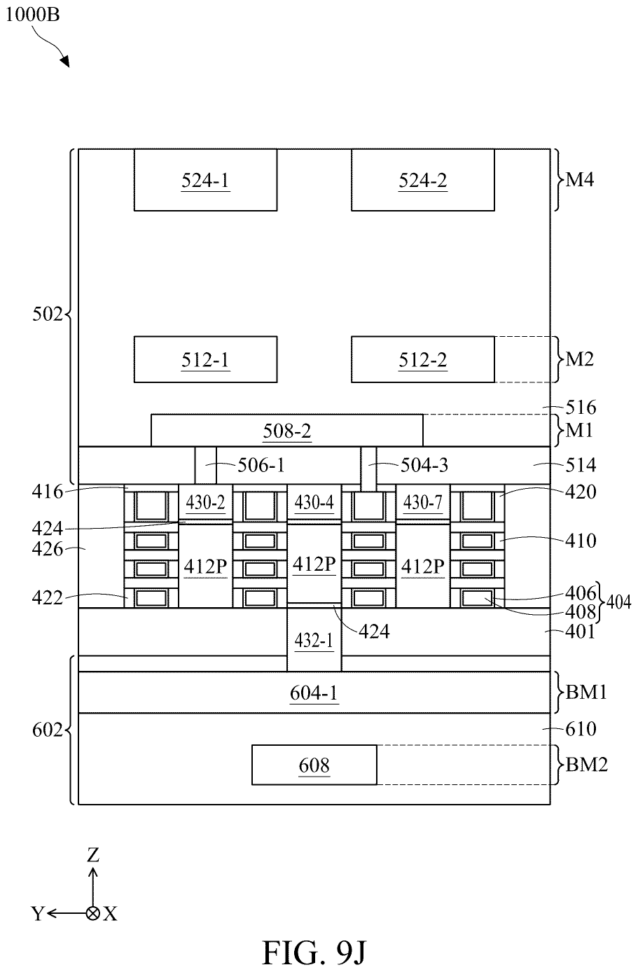

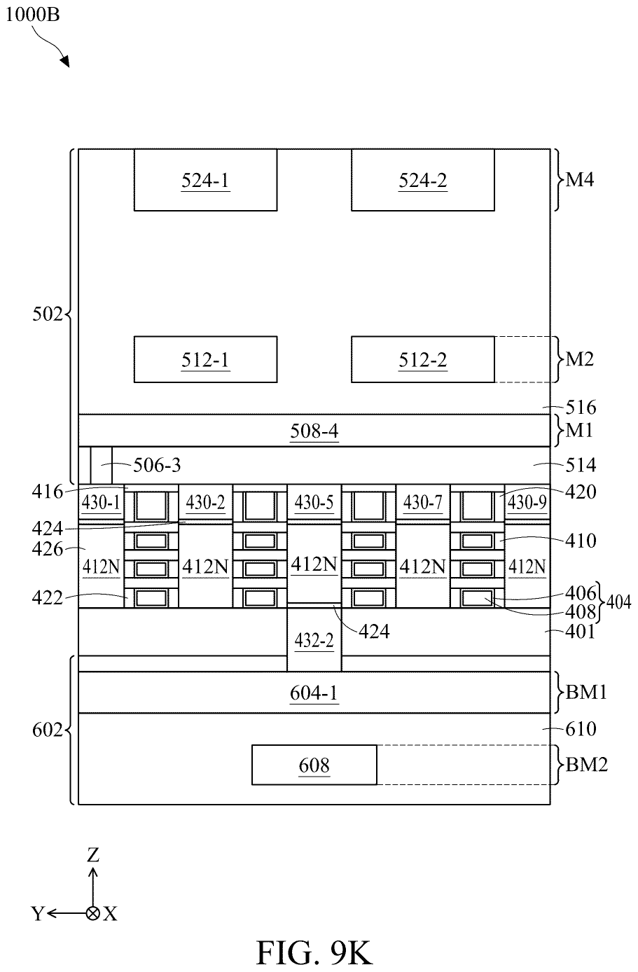

FIGS. 9A to 9D illustrate top views (or layouts) of features in a device region, a frontside interconnection structure, and a backside interconnection structure of two adjacent SRAM cells 100B and 100B′ in a portion of an array 1000B in a semiconductor device that can be one embodiment of the SRAM cells in adjacent two rows shown in FIG. 6, in accordance with some alternative embodiments of the present disclosure. FIG. 9A illustrates the features in the device region (including transistors) and the frontside interconnection structure including the metal conductors in the first metal layer (M1), and vias (V0, F_VG) vertically between the features and the first metal layer (M1). FIG. 9B illustrates the frontside interconnection structure including metal conductors in the first metal layer (M1), the second metal layer (M2), the third metal layer (M3), the fourth metal layer (M4), vias (V1) vertically between the first metal layer (M1) and the second metal layer (M2), vias (V2) vertically between the second metal layer (M2) and the third metal layer (M3), and vias (V3) vertically between the third metal layer (M3) and the fourth metal layer (M4). FIG. 9E illustrates the backside interconnection structure including the metal conductors in the second metal layer (BM1) and the third metal layer (BM2), and vias (BV1) vertically between the second metal layer (BM1) and the third metal layer (BM2).

FIG. 9F is an X-Z cross-sectional view of the array 1000B in the semiconductor device along a line F-F′ in FIGS. 9A to 9E, in accordance with some alternative embodiments of the present disclosure. FIG. 9G is an X-Z cross-sectional view of the array 1000B in the semiconductor device along a line G-G′ in FIGS. 9A to 9E, in accordance with some alternative embodiments of the present disclosure. FIG. 9H is a Y-Z cross-sectional view of the array 1000B in the semiconductor device along a line H-H′ in FIGS. 9A to 9E, in accordance with some alternative embodiments of the present disclosure. FIG. 9I is a Y-Z cross-sectional view of the array 1000B in the semiconductor device along a line I-I′ in FIGS. 9A to 9E, in accordance with some alternative embodiments of the present disclosure. FIG. 9J is a Y-Z cross-sectional view of the array 1000B in the semiconductor device along a line J-J′ in FIGS. 9A to 9E, in accordance with some alternative embodiments of the present disclosure. FIG. 9K is a Y-Z cross-sectional view of the array 1000B in the semiconductor device along a line K-K′ in FIGS. 9A to 9E, in accordance with some alternative embodiments of the present disclosure.

The SRAM cells 100B and 100B′ in the array 1000B are similar to the SRAM cells 100A and 100A′ in the array 1000A discussed above, except that the front-side interconnection structure 502 of the array 1000B further includes vias 518 (including vias 518-1 and 518-2), metal conductors 520 (including metal conductors 520-1 and 520-2), vias 522 (including vias 522-1 and 522-2), and metal conductors 524 (including metal conductors 524-1 and 524-2) in the IMD layer 516, which are over (or at the frontside of) the transistors in the SRAM cells 100A and 100A′ (e.g., the pass-gate transistors PG1, PG2, PG1′, and PG2′, the pull-down transistors PD1, PD2, PD1′, and PD2′, and the pull-up transistors PU1, PU2, PU1′, and PU2′).

The metal conductors 520 and 524 are respectively in the (front-side) metal layers M3 and M4, as discussed above. The metal layer M3 is over the metal layer M2 and the metal layer M4 is over the metal layer M3, and thus the metal conductors 520 are over the metal conductors 512 and the metal conductors 524 are over the metal conductors 520. As show in FIGS. 9A to 9D, the metal conductors 520 extend lengthwise in the Y-direction, and the metal conductors 524 extends lengthwise in the X-direction.

Each of the vias 518 are vertically between and electrically connected to the metal conductor 512 and the metal conductor 520. Each of the vias 522 are vertically between and electrically connected to the metal conductor 520 and the metal conductor 524. In some embodiments, the vias 518 and 522 may have a square shape in the top view. In other embodiments, the vias 518 and 522 may have a circular shape in the top view. The via 518 and the via 522 may be respectively similar to the via V2 and the via V3 discussed above. The via 518 and the via 522, the metal conductors 520 and 524 may also be referred to as front-side vias and front-side metal conductors, respectively.

In some embodiments, the metal conductors 524-1 and 524-2 also respectively serve as the word-lines WL discussed above that controls and electrically connected to the SRAM cells 100B and 100B′. More specifically, the metal conductor 524-1 serving as the word-line WL is electrically connected to the pass-gate transistors PG1 and PG2 in the SRAM cell 100B, and the metal conductor 524-2 serving as the word-line WL is electrically connected to the pass-gate transistors PG1′ and PG2′ in the SRAM cell 100B′.

As shown in FIGS. 9A to 9K, for the SRAM cell 100A, the metal conductor 524-1 is electrically connected to the metal conductor 512-1 serving as the word-line WL through the via 522-1, the metal conductor 520-1, and the via 518-1, such that the metal conductor 524-1 is also electrically connected to the gate structure 404-1 of the pass-gate transistor PG1 and the gate structure 404-4 of the pass-gate transistor PG2.

Similarly, for the SRAM cell 100A′, the metal conductor 524-2 is electrically connected to the metal conductor 512-2 serving as the word-line WL through the via 522-2, the metal conductor 520-2, and the via 518-2, such that the metal conductor 524-2 is also electrically connected to the gate structure 404-5 of the pass-gate transistor PG1′ and the gate structure 404-8 of the pass-gate transistor PG2′.

As shown in FIGS. 9A to 9D, in the top view, the vias 518-1 and 522-1 overlap the cell boundary CB, and the vias 518-2 and 522-2 overlap the cell boundary CB′. Furthermore, in the top view, the metal conductor 520-1 lengthwise overlaps the cell boundary CB, and the metal conductor 520-2 lengthwise overlaps the cell boundary CB′. In some embodiments, the metal conductors 524-1 and 524-2 may be referred to as (frontside) word-line conductors. In some embodiments, the metal conductors 520-1 and 520-2 may be referred to as write word-line landing pads.

Therefore, it can be seen as that the metal conductors 524 and the metal conductors 512 electrically connected with each other in parallel to serve as the word-lines WL, such that the total resistance of the metal conductors 524 and 512 are reduced, thereby improving the performance of the array 1000B.

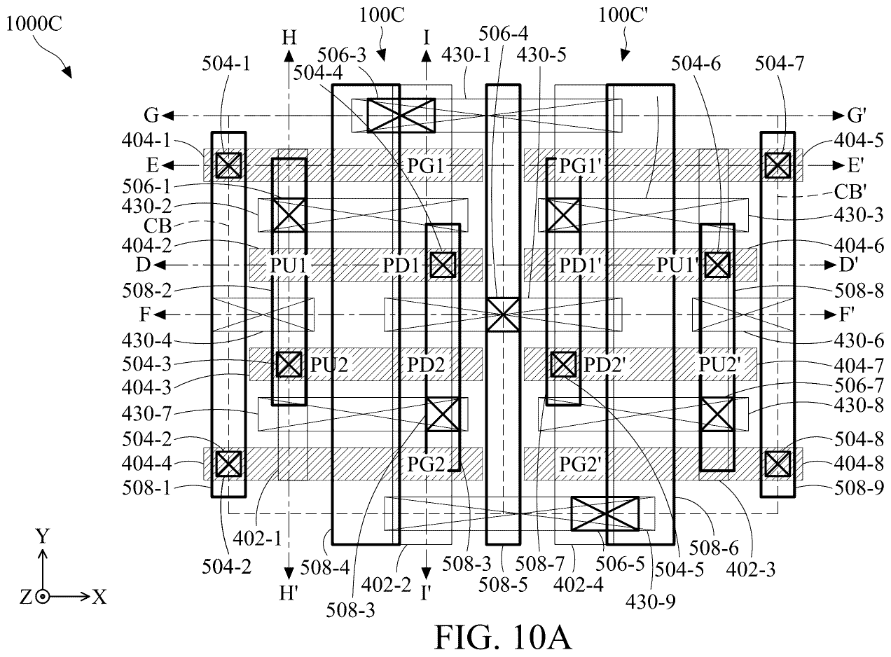

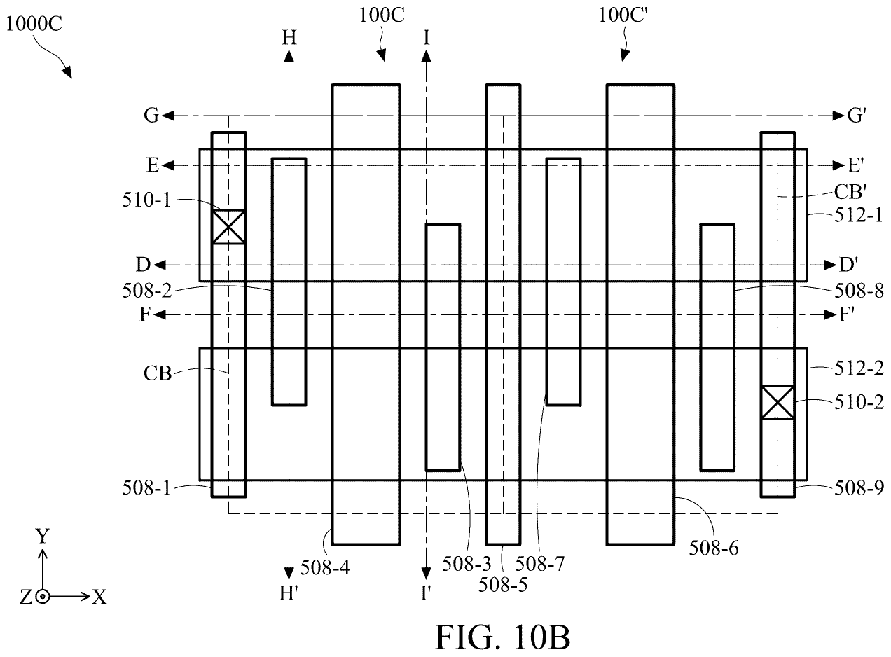

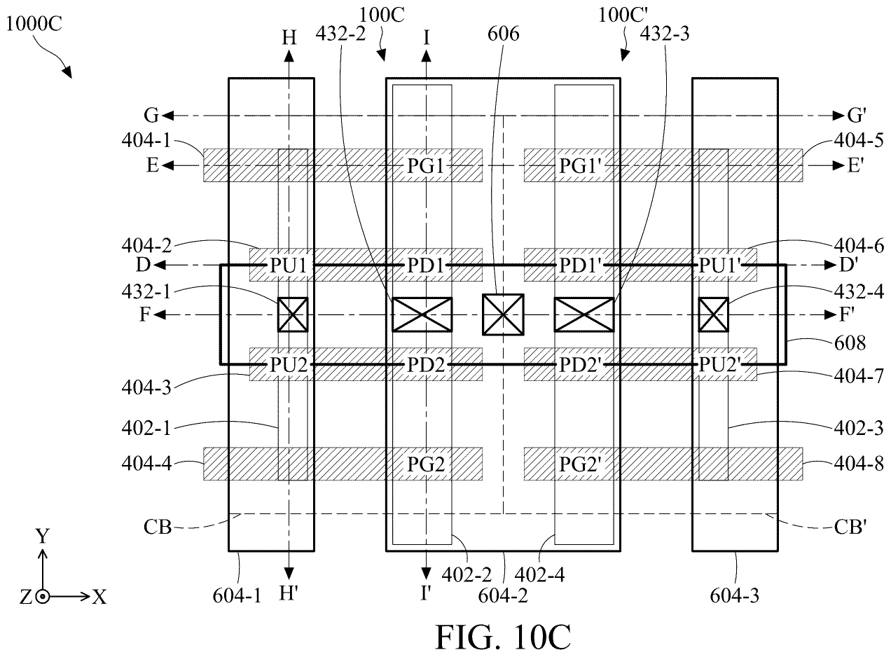

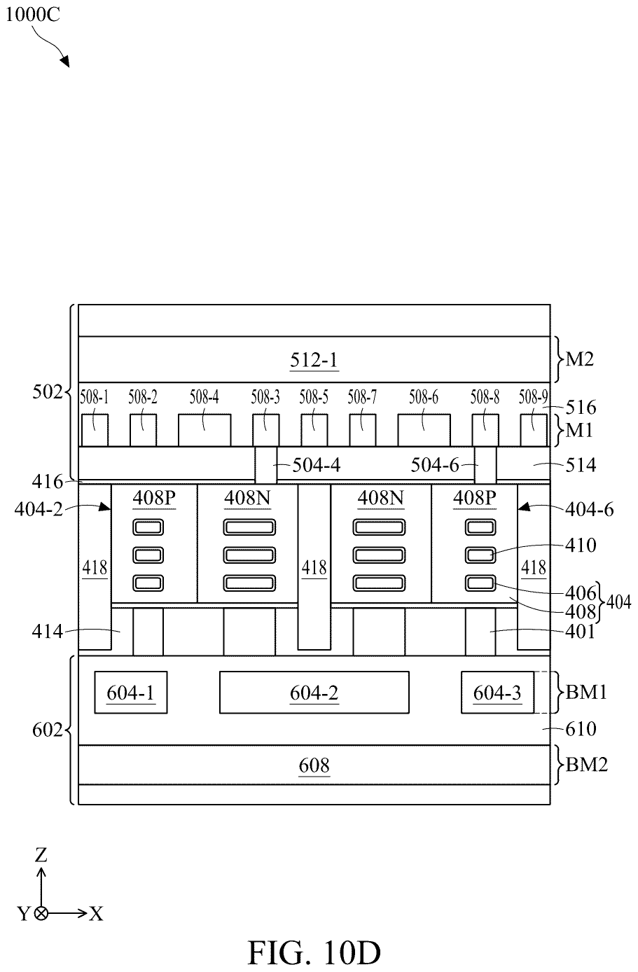

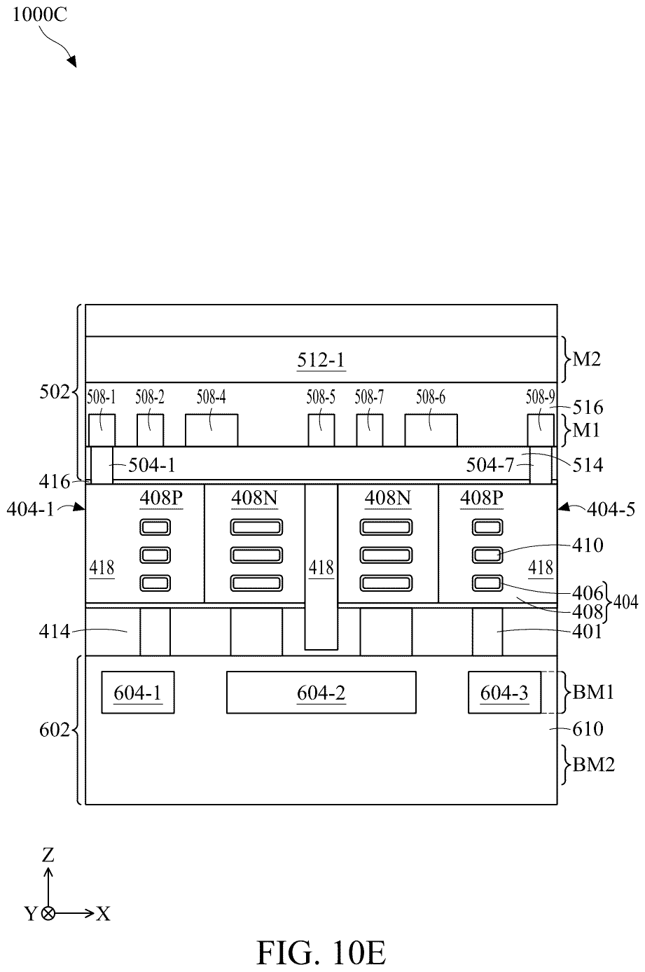

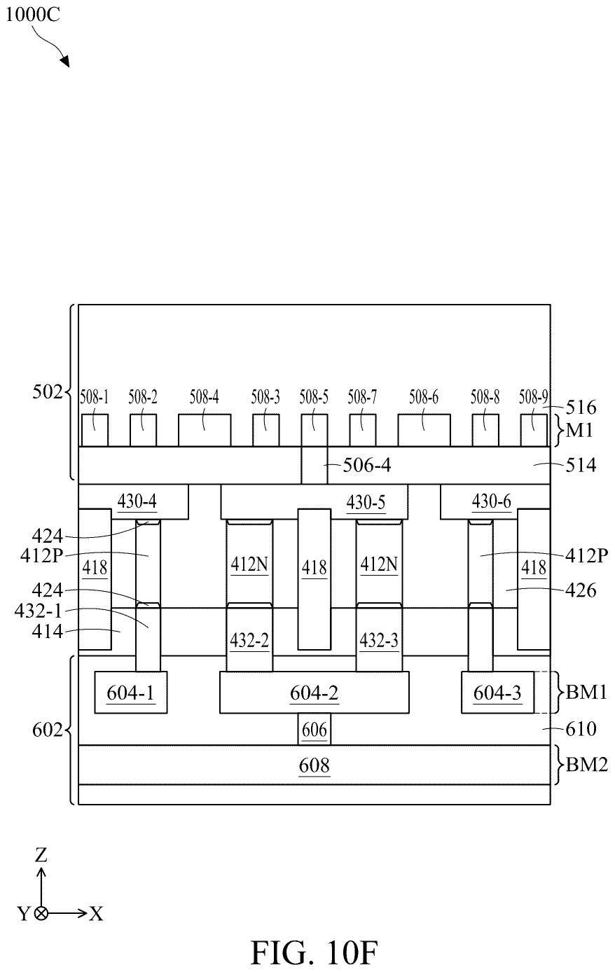

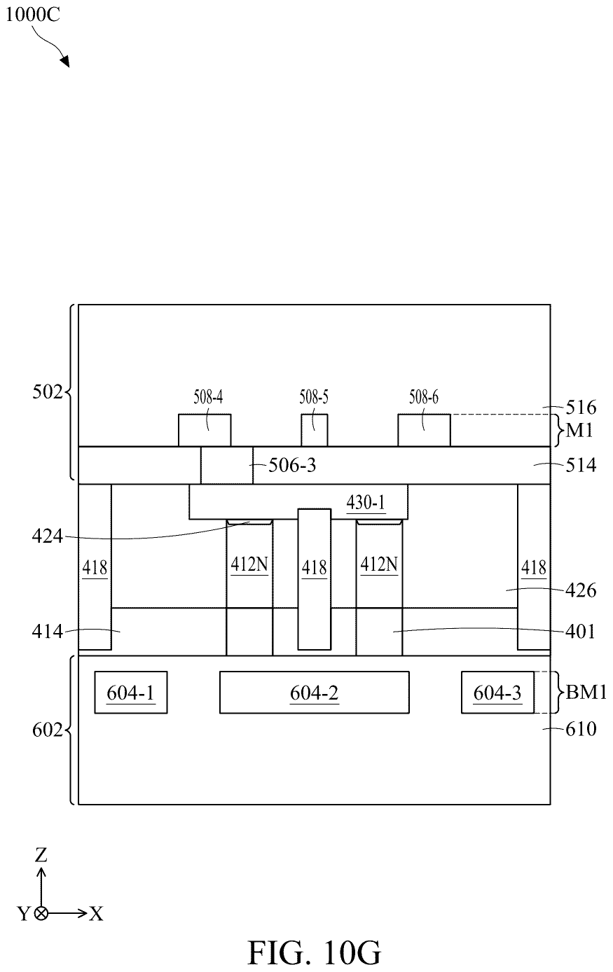

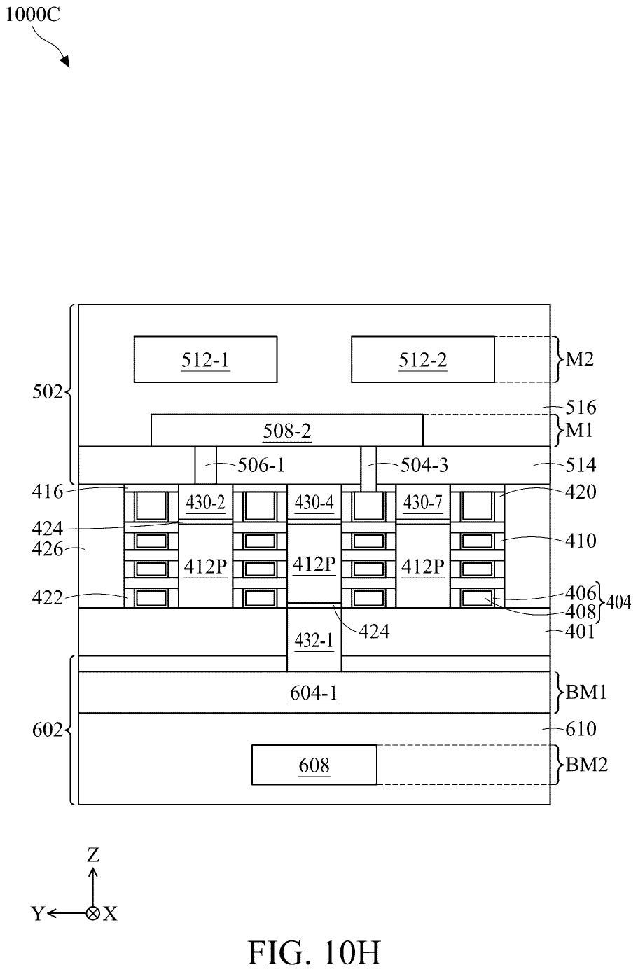

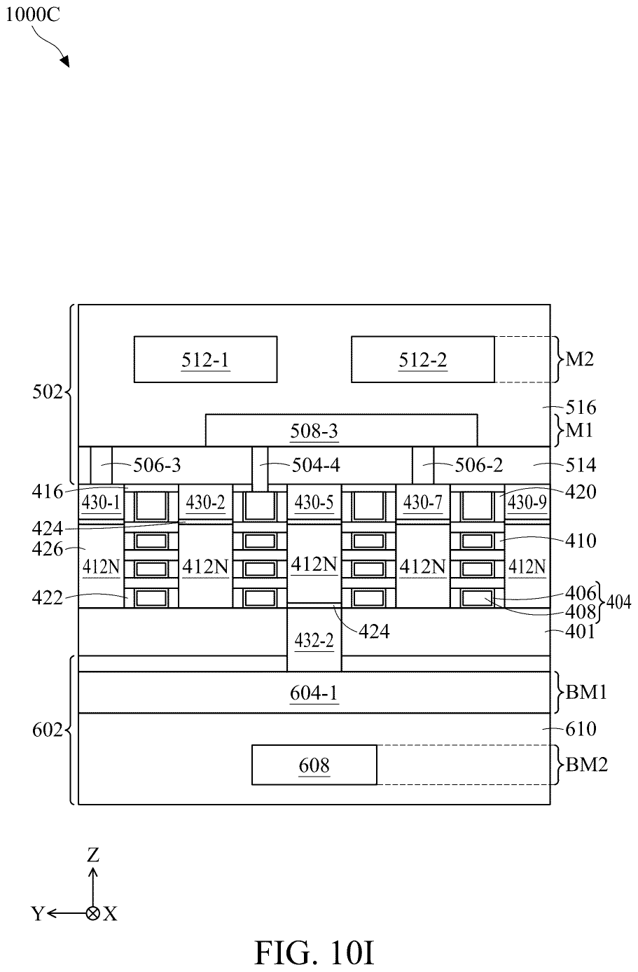

FIGS. 10A to 10C illustrate top views (or layouts) of features in a device region, a frontside interconnection structure, and a backside interconnection structure of two adjacent SRAM cells 100C and 100C′ in a portion of an array 1000C in a semiconductor device that can be one embodiment of the SRAM cells in adjacent two rows shown in FIG. 6, in accordance with some alternative embodiments of the present disclosure. FIG. 10A illustrates the features in the device region (including transistors) and the frontside interconnection structure including the metal conductors in the first metal layer (M1), and vias (V0, F_VG) vertically between the features and the first metal layer (M1). FIG. 10B illustrates the frontside interconnection structure including metal conductors in the first metal layer (M1) and the second metal layer (M2), and vias (V1) vertically between the first metal layer (M1) and the second metal layer (M2). FIG. 10C illustrates the backside interconnection structure including the metal conductors in the second metal layer (BM1) and the third metal layer (BM2), and vias (BV1) vertically between the second metal layer (BM1) and the third metal layer (BM2).

FIG. 10D is an X-Z cross-sectional view of the array 1000C in the semiconductor device along a line D-D′ in FIGS. 10A to 10C, in accordance with some alternative embodiments of the present disclosure. FIG. 10E is an X-Z cross-sectional view of the array 1000C in the semiconductor device along a line E-E′ in FIGS. 10A to 10C, in accordance with some alternative embodiments of the present disclosure. FIG. 10F is a Y-Z cross-sectional view of the array 1000C in the semiconductor device along a line F-F′ in FIGS. 10A to 10C, in accordance with some alternative embodiments of the present disclosure. FIG. 10G is a Y-Z cross-sectional view of the array 1000C in the semiconductor device along a line G-G′ in FIGS. 10A to 10C, in accordance with some alternative embodiments of the present disclosure. FIG. 10H is a Y-Z cross-sectional view of the array 1000C in the semiconductor device along a line H-H′ in FIGS. 10A to 10C, in accordance with some alternative embodiments of the present disclosure. FIG. 10I is a Y-Z cross-sectional view of the array 1000C in the semiconductor device along a line I-I′ in FIGS. 10A to 10C, in accordance with some alternative embodiments of the present disclosure.

The SRAM cells 100C and 100C′ in the array 1000C are similar to the SRAM cells 100A and 100A′ in the array 1000A discussed above, except that the locations of the gate vias 504-4 and 504-5, the vias 506-2, 506-3, 506-5, and 506-6, and metal conductors 508-3, 508-4, 508-6, and 508-7 in the SRAM cells 100C and 100C′ in the array 1000C are different than that in the SRAM cells 100A and 100A′ in the array 1000A.

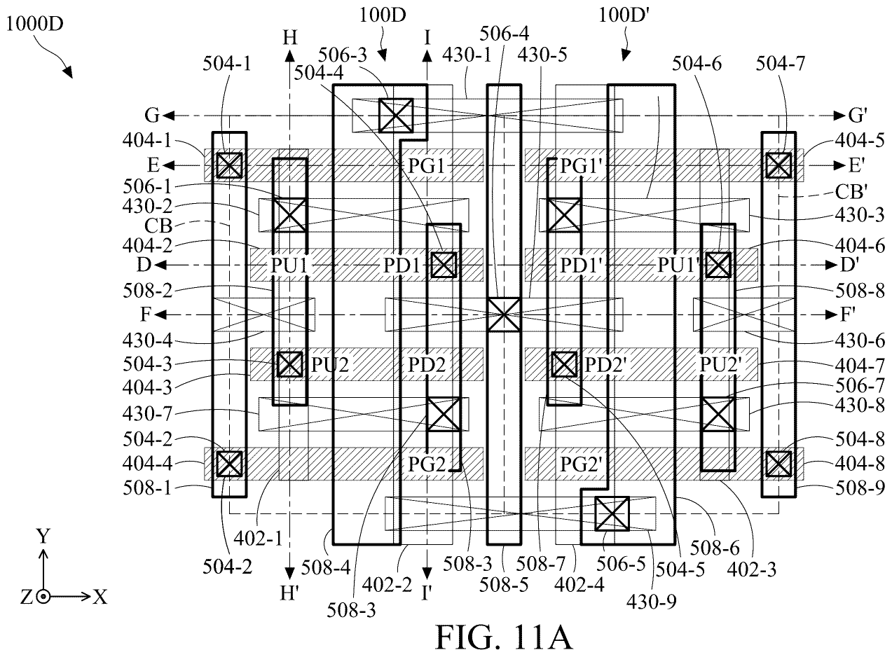

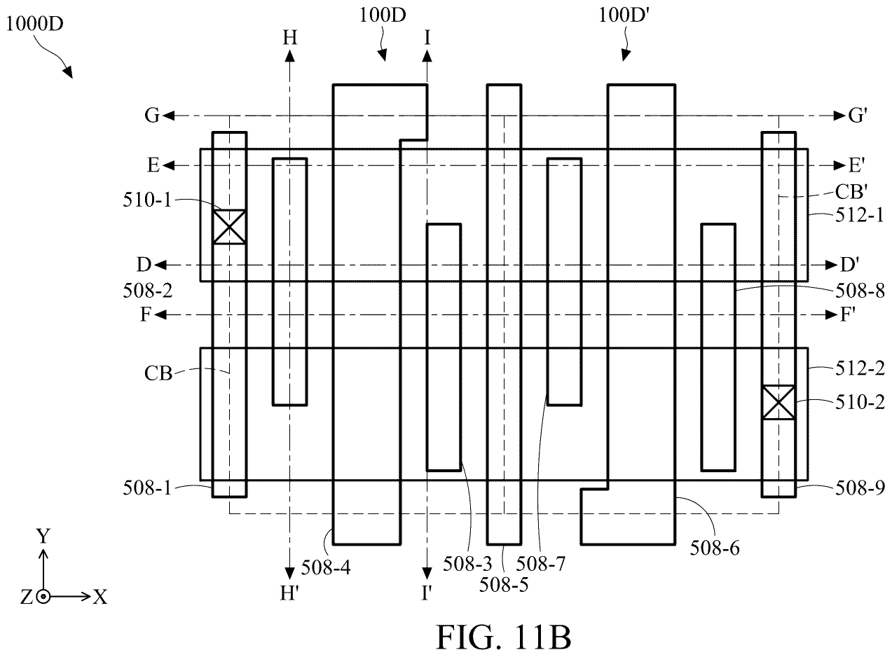

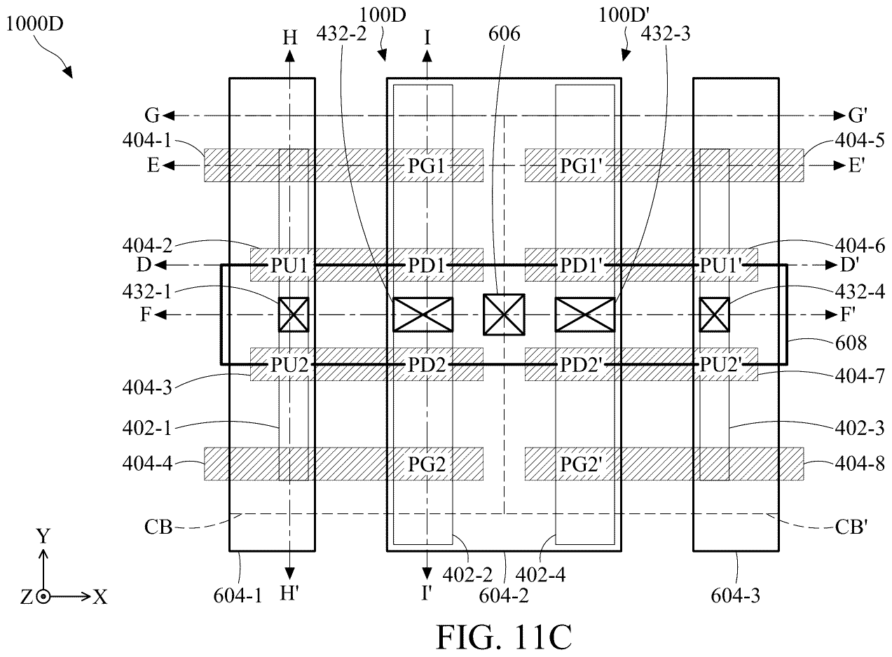

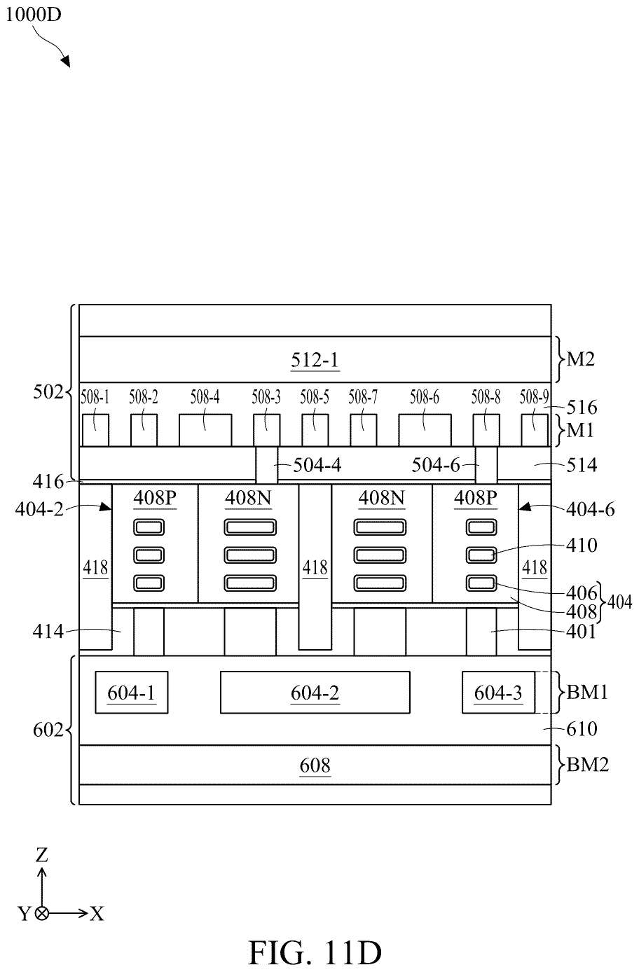

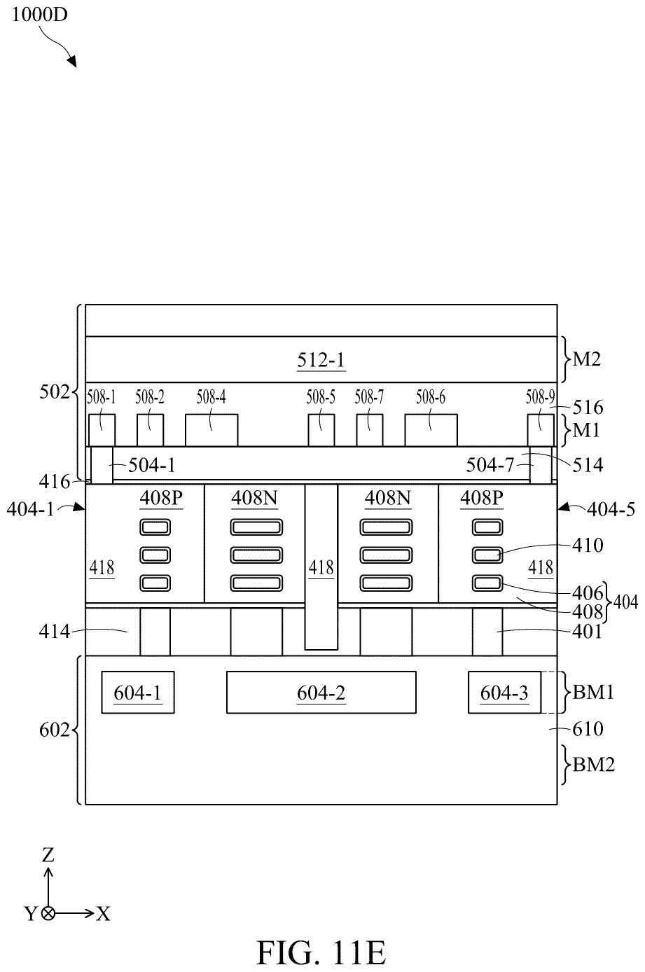

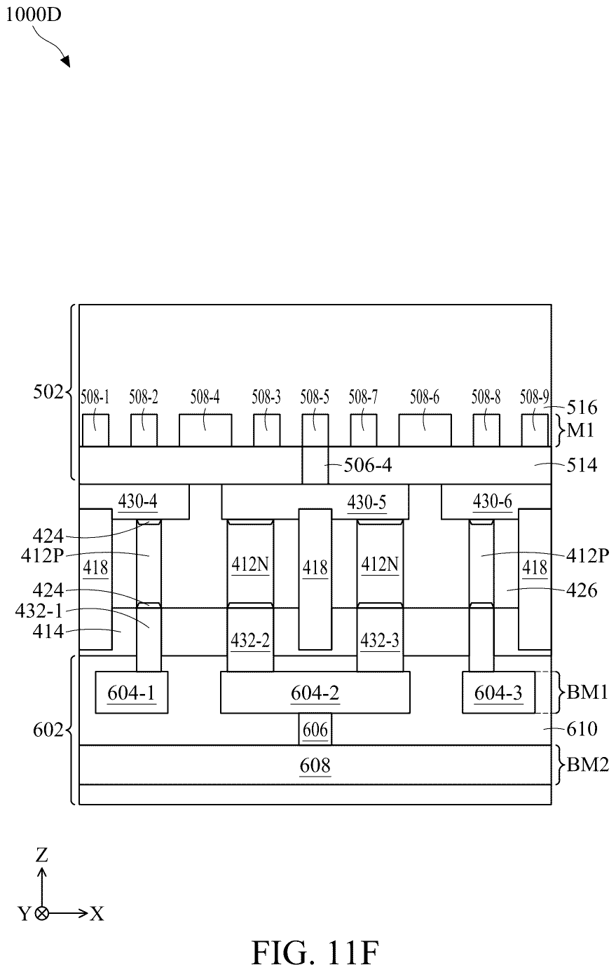

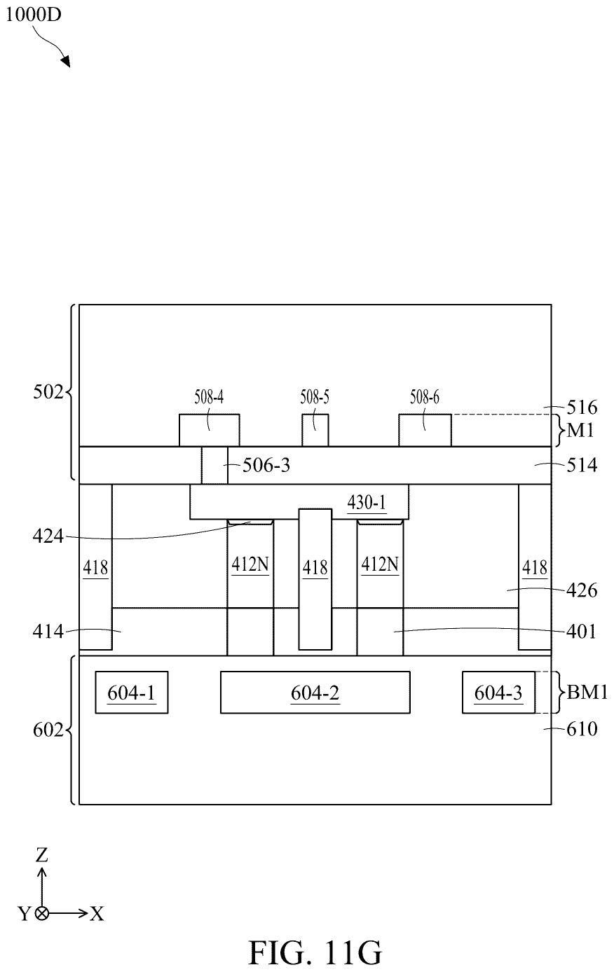

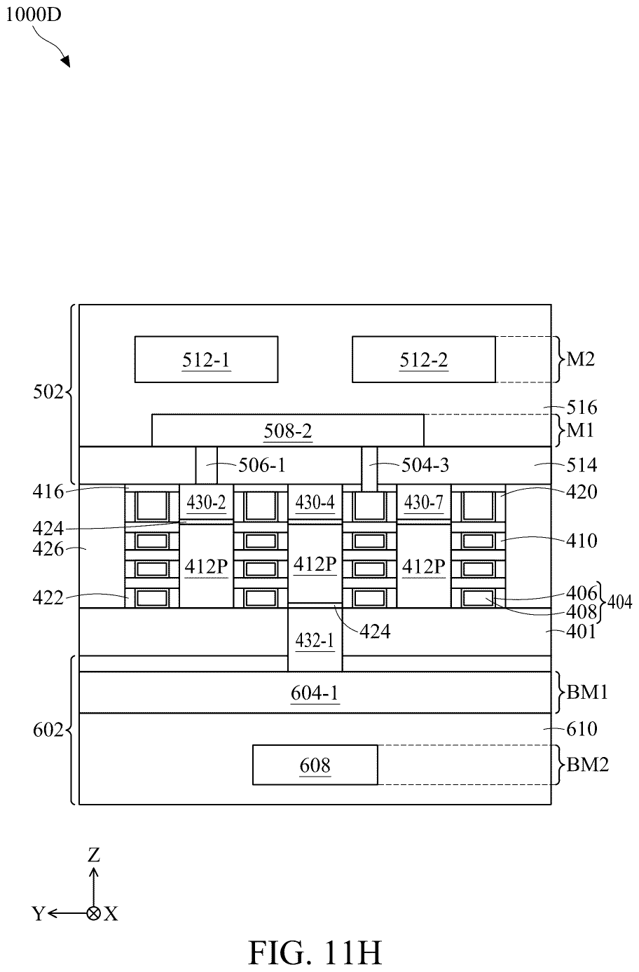

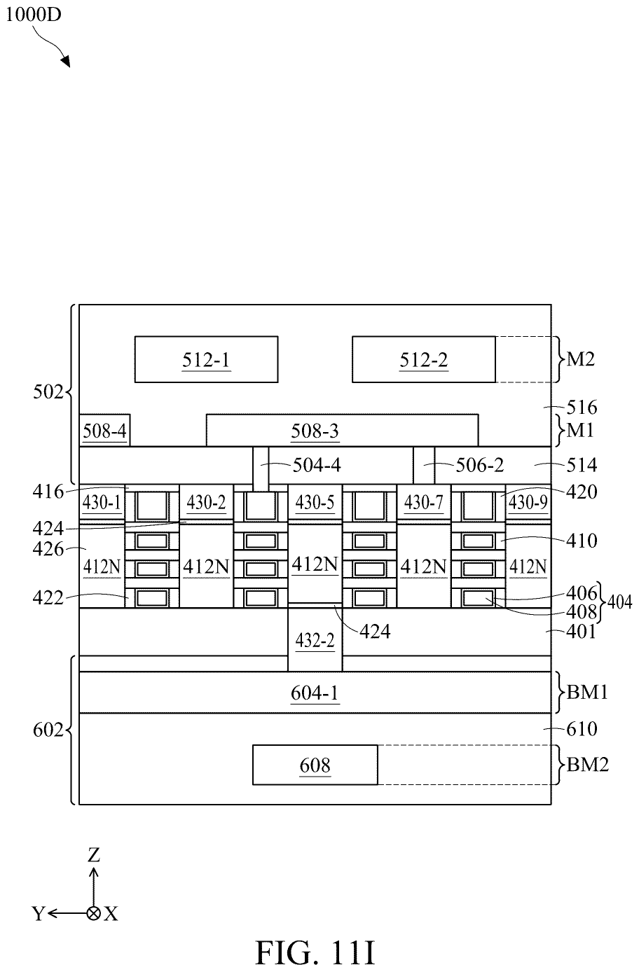

Referring back to FIGS. 7A to 7I, the metal conductor 508-4 is between the metal conductors 506-3 and 506-5 in the X-direction, and the metal conductor 508-6 is between the metal conductors 506-5 and 506-7 in the X-direction. As shown in FIGS. 10A to 10I, the metal conductor 508-3 is between the metal conductors 506-4 and 506-5 in the X-direction, and the metal conductor 508-7 is between the metal conductors 506-5 and 506-6 in the X-direction. In other words, the metal conductors 508-4 and 508-6 respectively serving as the bit-line BL and the bit-line-bar BLB are farther separated or spaced apart from the metal conductor 508-5 serving as the VSS line in the X-direction in FIGS. 11A to 11I compared to FIGS. 7A to 7I.

As discussed above, the metal conductors 508-4 and 508-6 respectively serving as the bit-line BL and the bit-line-bar BLB are more concerned about the capacitance. Since the metal conductors 508-4 and 508-6, respectively serving as the bit-line BL and the bit-line-bar BLB, and the metal conductor 508-5, serving as the VSS line, extend in the Y-direction along the entire column of the array 1000C, the farther apart the metal conductors 508-4 and 508-6 (bit-line BL and bit-line-bar BLB) and the metal conductor 508-5 (VSS line) are, the smaller the capacitance between them will be. Therefore, the capacitance between the metal conductors 508-4 and 508-6 respectively serving as the bit-line BL and the bit-line-bar BLB and the metal conductor 508-5 serving as the VSS line are reduced, thereby improving the performance of the semiconductor devices.

Furthermore, as shown in FIGS. 10A to 10I, the vias 506-3 and 506-5 in the top view have a rectangular shape extending in the X-direction. Therefore, the vias 506-3 and 506-5 have larger volumes to achieve lower resistance, thereby improving the performance of the array 1000C. Such vias 506-3 and 506-5 may also be referred to as slot vias. In some embodiments, the metal conductors 508-4 and 508-6 partially cover and are partially attached to top surfaces of the vias 506-3 and 506-5, respectively, as shown in FIGS. 10A and 10G.

FIGS. 11A to 11C illustrate top views (or layouts) of features in a device region, a frontside interconnection structure, and a backside interconnection structure of two adjacent SRAM cells 100D and 100D′ in a portion of an array 1000D in a semiconductor device that can be one embodiment of the SRAM cells in adjacent two rows shown in FIG. 6, in accordance with some alternative embodiments of the present disclosure. FIG. 11A illustrates the features in the device region (including transistors) and the frontside interconnection structure including the metal conductors in the first metal layer (M1), and vias (V0, F_VG) vertically between the features and the first metal layer (M1). FIG. 11B illustrates the frontside interconnection structure including metal conductors in the first metal layer (M1) and the second metal layer (M2), and vias (V1) vertically between the first metal layer (M1) and the second metal layer (M2). FIG. 11C illustrates the backside interconnection structure including the metal conductors in the second metal layer (BM1) and the third metal layer (BM2), and vias (BV1) vertically between the second metal layer (BM1) and the third metal layer (BM2).

FIG. 11D is an X-Z cross-sectional view of the array 1000D in the semiconductor device along a line D-D′ in FIGS. 11A to 11C, in accordance with some alternative embodiments of the present disclosure. FIG. 11E is an X-Z cross-sectional view of the array 1000D in the semiconductor device along a line E-E′ in FIGS. 11A to 11C, in accordance with some alternative embodiments of the present disclosure. FIG. 11F is a Y-Z cross-sectional view of the array 1000D in the semiconductor device along a line F-F′ in FIGS. 11A to 11C, in accordance with some alternative embodiments of the present disclosure. FIG. 11G is a Y-Z cross-sectional view of the array 1000D in the semiconductor device along a line G-G′ in FIGS. 11A to 11C, in accordance with some alternative embodiments of the present disclosure. FIG. 11H is a Y-Z cross-sectional view of the array 1000D in the semiconductor device along a line H-H′ in FIGS. 11A to 11C, in accordance with some alternative embodiments of the present disclosure. FIG. 11I is a Y-Z cross-sectional view of the array 1000D in the semiconductor device along a line I-I′ in FIGS. 11A to 11C, in accordance with some alternative embodiments of the present disclosure.

The SRAM cells 100D and 100D′ in the array 1000D are similar to the SRAM cells 100C and 100C′ in the array 1000C discussed above, except that the metal conductors 508-4 and 508-6 respectively serving as the bit-line BL and the bit-line-bar BLB have asymmetric shapes in the top view. As shown in FIGS. 11A to 11I, in the top view, each of the metal conductor 508-4 serving as the bit-line BL and the metal conductor 508-6 serving as the bit-line-bar BL has a L-shape.

Furthermore, as shown in FIGS. 11A to 11I, the vias 506-3 and 506-5 in the top view have a square shape. In some embodiments, the metal conductors 508-4 and 508-6 have L-shapes to fully cover and are fully attached to the top surfaces of the vias 506-3 and 506-5, respectively, as shown in FIGS. 10A and 10G. Therefore, the metal conductors 508-4 and 508-6 and the vias 506-3 and 506-5 have larger contact area to achieve lower resistance, thereby improving the performance of the array 1000D.

The embodiments disclosed herein relate to semiconductor devices, and more particularly to semiconductor devices including metal conductors for the bit-line and the bit-line-bar that are shared by two SRAM cells in adjacent two rows of an SRAM array, in which the metal conductors are in the lowest metal layer (the metal layer M1), that can improve cell performance of the SRAM cells. Furthermore, the present embodiments provide one or more of the following advantages. The metal conductors for word-lines in the higher metal layers may have a wider width to provide a lower circuit resistance, which improves the performance of the SRAM cells, such as RC delay. In addition, the metal conductors for VDD lines and VSS lines are disposed in the back-side interconnection structure under the SRAM cells to relieve the space at the front-side interconnection structure. The metal conductors for VDD lines and VSS lines are also in the lowest metal layer (the metal layer BM1) to have lower capacitance, thereby improving the performance of the semiconductor devices.

Thus, one of the embodiments of the present disclosure describes a semiconductor device that includes a first transistor cell having a first cell boundary lengthwise extending in a first direction. The first transistor cell includes a first active area and a second active area extending in the first direction and arranged in a second direction perpendicular to the first direction, an isolation feature between the first active area and the second active area, and gate structures across the first active area and the second active area and interfacing a top surface of the isolation feature. The semiconductor device further includes a first backside power conductor under and lengthwise overlapping the first active area and a second backside power conductor under and lengthwise overlapping the second active area. The first backside power conductor and the second backside power conductor are electrically connected to the first transistor cell.

In another of the embodiments, discussed is a semiconductor device including aa first transistor cell and a second transistor cell having rectangular cell boundaries lengthwise extending in a first direction and arranged in a second direction perpendicular to the first direction, a first active area and a second active area in the first transistor cell, and a third active area and a fourth active area in the second transistor cell. Each of the first active area, the second active area, the third active area, and the fourth active area includes channel layers, source/drain features attached to the channel layers, and gate structures interfacing at least three surfaces of each of the channel layers. The semiconductor device further includes a source/drain contact extending in the second direction and electrically connected to the source/drain features of the second active area and the fourth active area, an inter-layer dielectric layer surrounding the source/drain contact, and a first backside metal layer under the first active area, the second active area, the third active area, and the fourth active area. The conductivity of the source/drain contact is greater than that of the source/drain features. The first backside metal layer includes a first VDD conductor electrically connected to the first transistor cell, a second VDD conductor electrically connected to the second transistor cell, and a first VSS conductor electrically connected to the first transistor cell and the second transistor cell.

In yet another of the embodiments, discussed is a semiconductor device that includes a first transistor cell and a second transistor cell arranged in a first direction. The first transistor cell includes first transistors arranged in a second direction and having a first channel width in the first direction, and second transistors arranged in the second direction and having a second channel width in the first direction. The second direction is perpendicular to the first direction. The second transistor cell includes third transistors arranged in the second direction and having the first channel width in the first direction, and fourth transistors arranged in the second direction and having the second channel width in the first direction. The semiconductor device further includes a first backside power conductor under and electrically connected to the first transistors, a second backside power conductor under and electrically connected to the third transistors, and a third backside power conductor under and electrically connected to the second transistors and the fourth transistors. The first channel width is less than the second channel width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first transistor cell having a first cell boundary lengthwise extending in a first direction, wherein the first transistor cell comprises:
a first active area and a second active area extending in the first direction and arranged in a second direction perpendicular to the first direction;
an isolation feature between the first active area and the second active area; and
gate structures across the first active area and the second active area and interfacing a top surface of the isolation feature;
a first backside power conductor under and lengthwise overlapping the first active area; and
a second backside power conductor under and lengthwise overlapping the second active area,
wherein the first backside power conductor and the second backside power conductor are electrically connected to the first transistor cell.

2. The semiconductor device of claim 1, further comprising:
a second transistor cell having a second cell boundary lengthwise extending in the first direction and arranged with the first transistor cell in the second direction, wherein the second transistor cell comprises:
a third active area and a fourth active area extending in the first direction and arranged in the second direction; and
a third backside power conductor under and lengthwise overlapping the third active area,
wherein the second backside power conductor under and lengthwise overlapping the fourth active area.

3. The semiconductor device of claim 2, further comprising:
a first pull-up transistor and a second pull-up transistor sharing the first active area;
a first pass-gate transistor, a second pass-gate transistor, a first pull-down transistor, and a second pull-down transistor sharing the second active area;
a third pull-up transistor and a fourth pull-up transistor sharing the third active area; and
a third pass-gate transistor, a fourth pass-gate transistor, a third pull-down transistor, and a fourth pull-down transistor sharing the fourth active area.

4. The semiconductor device of claim 2, further comprising:
a bit-line conductor over and electrically connected to the first pass-gate transistor and the third pass-gate transistor; and
a bit-line-bar conductor over and electrically connected to the second pass-gate transistor and the fourth pass-gate transistor,
wherein the bit-line conductor extends extending in the first direction and crosses the first cell boundary,
wherein the bit-line-bar conductor extends extending in the first direction and crosses the second cell boundary.

5. The semiconductor device of claim 4, further comprising:
a first word-line conductor and a second word-line conductor over the bit-line conductor and the bit-line-bar conductor,
wherein the first word-line conductor extends in the second direction and is electrically connected to the first pass-gate transistor and the second pass-gate transistor,
wherein the second word-line conductor extends in the second direction and is electrically connected to the third pass-gate transistor and the fourth pass-gate transistor.

6. The semiconductor device of claim 5, further comprising:
a third word-line conductor and a fourth word-line conductor over the first word-line conductor and the second word-line conductor,
wherein the third word-line conductor extends in the second direction and is electrically connected to the first word-line conductor,
wherein a fourth word-line conductor extends in the second direction and is electrically connected to the second word-line conductor.

7. The semiconductor device of claim 4, wherein each of the bit-line conductor and the bit-line-bar conductor has a L-shape in a top view.

8. The semiconductor device of claim 4, further comprising:
slot vias extending in the second direction and under the bit-line conductor and the bit-line-bar conductor, wherein the bit-line conductor and the bit-line-bar conductor are partially attached to top surfaces of the slot vias.

9. The semiconductor device of claim 2, further comprising:
a frontside power conductor over and lengthwise overlapping the first cell boundary and the second cell boundary, wherein the frontside power conductor is electrically connected to the first transistor cell and the second transistor cell.

10. A semiconductor device, comprising:
a first transistor cell and a second transistor cell having rectangular cell boundaries lengthwise extending in a first direction and arranged in a second direction perpendicular to the first direction;
a first active area and a second active area in the first transistor cell;
a third active area and a fourth active area in the second transistor cell, wherein each of the first active area, the second active area, the third active area, and the fourth active area comprises:
channel layers;
source/drain features attached to the channel layers; and
gate structures interfacing at least three surfaces of each of the channel layers;
a source/drain contact extending in the second direction and electrically connected to the source/drain features of the second active area and the fourth active area, wherein conductivity of the source/drain contact is greater than that of the source/drain features;
an inter-layer dielectric layer surrounding the source/drain contact; and
a first backside metal layer under the first active area, the second active area, the third active area, and the fourth active area, wherein the first backside metal layer comprises a first VDD conductor electrically connected to the first transistor cell, a second VDD conductor electrically connected to the second transistor cell, and a first VSS conductor electrically connected to the first transistor cell and the second transistor cell.

11. The semiconductor device of claim 10, further comprising:
a first frontside metal layer over the further first active area, the second active area, the third active area, and the fourth active area, wherein the first frontside metal layer comprises a second VSS conductor electrically connected to the first transistor cell and the second transistor cell.

12. The semiconductor device of claim 11, wherein the first frontside metal layer further comprises:
a bit-line conductor electrically connected to first pass-gate transistors of the first transistor cell and the second transistor cell; and
a bit-line-bar conductor electrically connected to second pass-gate transistors of the first transistor cell and the second transistor cell.

13. The semiconductor device of claim 12, further comprising:
a second frontside metal layer over the first frontside metal layer, wherein the second frontside metal layer comprises:
a first word-line conductor electrically connected to the first pass-gate transistor and the second pass-gate transistor of the first transistor cell; and
a second word-line conductor electrically connected to the first pass-gate transistor and the second pass-gate transistor of the second transistor cell.

14. The semiconductor device of claim 13, further comprising:
a third frontside metal layer over the second frontside metal layer, wherein the third frontside metal layer comprises:
a third word-line conductor electrically connected to the first word-line conductor; and
a fourth word-line conductor electrically connected to the second word-line conductor.

15. The semiconductor device of claim 12, wherein each of the bit-line conductor and the bit-line-bar conductor has an asymmetric shape in a top view.

16. The semiconductor device of claim 10, further comprising:
a second backside metal layer under the first backside metal layer, wherein the second backside metal layer comprises a second VSS conductor electrically connected to the first VSS conductor.

17. A semiconductor device, comprising:
a first transistor cell and a second transistor cell arranged in a first direction, wherein the first transistor cell comprises:
first transistors arranged in a second direction and having a first channel width in the first direction, wherein the second direction is perpendicular to the first direction; and
second transistors arranged in the second direction and having a second channel width in the first direction,
wherein the second transistor cell comprises:
third transistors arranged in the second direction and having the first channel width in the first direction; and
fourth transistors arranged in the second direction and having the second channel width in the first direction;
a first backside power conductor under and electrically connected to the first transistors;
a second backside power conductor under and electrically connected to the third transistors; and
a third backside power conductor under and electrically connected to the second transistors and the fourth transistors,
wherein the first channel width is less than the second channel width.

18. The semiconductor device of claim 17,
wherein the first transistors comprise a first pull-up transistor and a second pull-up transistor sharing a first active area,
wherein the second transistors comprise a first pass-gate transistor, a second pass-gate transistor, a first pull-down transistor, and a second pull-down transistor sharing a second active area,
wherein the third transistors comprise a third pull-up transistor and a fourth pull-up transistor sharing a third active area,
wherein the fourth transistors comprise a third pass-gate transistor, a fourth pass-gate transistor, a third pull-down transistor, and a fourth pull-down transistor sharing a fourth active area.

19. The semiconductor device of claim 18, further comprising:
a bit-line conductor over and electrically connected to source/drain features of the first pass-gate transistor and the third pass-gate transistor; and
a bit-line-bar conductor over and electrically connected to source/drain features of the second pass-gate transistor and the fourth pass-gate transistor.

20. The semiconductor device of claim 19, further comprising:
a source/drain contact over and electrically connected to a source/drain feature shared by the first pull-down transistor and the second pull-down transistor and a source/drain feature shared by the third pull-down transistor and the fourth pull-down transistor; and
a first frontside power conductor over and electrically connected to the source/drain contact, wherein the first frontside power conductor is between the bit-line conductor and the bit-line-bar conductor in the first direction.
